(19) United States
(12) Patent Application Publication
(10) Pub. No.: US 2026/0205002 A1
(43) Pub. Date: Jul. 16, 2026

(54) SYSTEMS AND METHODS FOR CONSTANT ON-TIME CONTROL FOR CONVERTERS

(71) Applicant: DIGIQ POWER LTD., Kingston (CA)

(72) Inventors: Sina SALEHI DOBAKHSHARI, Kingston (CA); Yang CHEN, Kingston (CA); Binghui HE, Kingston (CA); Yan-Fei LIU, Kingston (CA)

(21) Appl. No.: 19/448,412

(22) Filed: Jan. 14, 2026

Related U.S. Application Data
(60) Provisional application No. 63/745,283, filed on Jan. 14, 2025.
(60) Provisional application No. 63/745,285, filed on Jan. 14, 2025.

(51) Int. Cl. H02M 1/00; H02M 1/084; H02M 1/088; H02M 3/00; H03K 17/081

(52) U.S. Cl. CPC H02M 1/0058; H02M 1/0009; H02M 1/084; H02M 1/088; H02M 3/01; H03K 17/08104

(57) ABSTRACT

A system and method is proposed for constant-on time control of a converter for regulation of an output DC voltage. The system and method include a converter having a transformer with a primary side coupled in series with a switching network having at least two switches, where a switching frequency is set for the switches to regulate the output DC voltage, and the switching frequency has a corresponding switching period. The switches are modulated 180 degrees out of phase between an on-state and an off-state, and the switches are kept in the on-state for a fixed time duration that is at most half the switching period.

### CROSS REFERENCE

This application claims all benefit, including priority, to U.S. provisional applications No. 63/745,283 and No. 63/745,285, both filed on Jan. 14, 2025, the contents of which are hereby incorporated by reference.

### FIELD

Embodiments of the present disclosure relate to the field of electrical circuitry, and more specifically, embodiments relate to devices, systems and methods for constant on-time control for converters.

### INTRODUCTION

Converting an input DC voltage to an AC voltage (i.e. grid voltage), or vice-versa, is common in battery charging and discharging circuits which typically contain a two-stage topology. The first stage is responsible for increasing the input DC voltage to improve efficiency of the proceeding DC-AC conversion, this is typically performed by a step-up DC-DC converter. The second stage is responsible for the AC-DC conversion and is performed by an inverter. Step-up DC-DC converters for usage in the first stage can include, for example, full-bridge or push-pull LLC converters which perform voltage regulation through variable switching frequency control using a constant duty cycle for the primary switches. When using a full-bridge LLC converter, the conduction losses on the primary side are doubled compared to the push-pull LLC converter due to the two additional primary switches. However, to achieve effective voltage regulation for the push-pull LLC converter under variable switching frequency control, a high switching frequency and/or turn-off current for the primary switches is required, resulting in increased switching losses that impact the efficiency of the DC-AC conversion. Therefore, improvements in variable switching frequency control for DC-DC converters are desired.

### SUMMARY

A method for constant on-time control of a push-pull LLC converter is proposed. In some embodiments, the converter has a transformer with a primary side coupled in series with a switching network having two switches Q1 and Q2, and a secondary side coupled to a resonant tank and a rectifier, where the primary side receives an input DC voltage supply and the rectifier outputs a DC bus voltage. The method for constant on-time control of the converter includes setting a switching frequency for the switches Q1 and Q2 to regulate the DC bus voltage, the switching frequency having a corresponding switching period representing a full cycle of both switches Q1 and Q2, and modulating the switches Q1 and Q2 180 degrees out of phase between an on-state and an off-state, and switches Q1 and Q2 are kept in the on-state for a fixed time duration that is at most half the switching period.

In some embodiments, the method for constant on-time control further comprises generating, from a gate driver, a gate voltage for each of the primary switches Q1 and Q2 to transition each of the primary switches between the on-state and the off-state during the switching period, the primary switches entering the on-state upon receiving a high gate voltage and entering the off-state upon receiving a low gate voltage.

In some embodiments, the method for constant on-time control further comprises transmitting, at the start of the switching period, the high gate voltage to the primary switch Q1 for a first fixed time duration to transition the primary switch Q1 to the on-state, transmitting, upon expiry of the first fixed time duration, the low gate voltage to the primary switch Q1 to transition the primary switch Q1 to the off-state, transmitting, at a half point of the switching period, the high gate voltage to the primary switch Q2 for a second fixed time duration to transition the primary switch Q2 to the on-state, transmitting, upon expiry of the second fixed time duration, the low gate voltage to the primary switch Q2 to transition the primary switch Q2 to the off-state, and sensing the DC bus voltage, through a voltage sensor, and setting a modified switching frequency of the primary switches based on a delta between the sensed DC bus voltage and a desired DC bus voltage.

In some embodiments, the modified switching frequency is lower than a resonant frequency of the resonant tank.

In some embodiments, the rectifier is one of a voltage multiplier, full-bridge or half-bridge topography.

In some embodiments, the converter has two transformers coupled in parallel to the input DC voltage, where the primary side of the first transformer is connected to the switching network containing the primary switches Q1 and Q2, and the second transformer is connected to a second switching network containing primary switches Q3 and Q4, and the gate voltage generated by the gate driver for the primary switch Q3 is the same as the gate voltage for the primary switch Q1, and the game voltage generated by the gate driver for the primary switch Q4 Is the same as the gate driver voltage generated for the primary switch Q2.

In some embodiments, the secondary side of the first and second transformers are coupled in series to the resonant tank and the rectifier.

In some embodiments, transitioning the primary switches Q1 and Q2 from the on-state to the off-state occurs after a peak primary side magnetizing current is equal to a switch current, wherein the peak primary side magnetizing current is a measure of current flow across a magnetizing inductor of the transformer multiplied by the turn ratio of the transformer, and the switch current is a measure of current flow across the primary switches Q1 and Q2 when they are in the on-state.

In some embodiments, both primary switches Q1 and Q2 are in the off-state between the expiry of the fixed time duration and the half point of the switching period.

A method for constant on-time control of a push-pull LLC converter is proposed. In some embodiments, the converter has a transformer with a primary side coupled in series to a switching network with four switches Q1-Q4, and a secondary side coupled to a resonant tank and a rectifier, where the primary side receives an input DC voltage supply and the rectifier outputs a DC bus voltage. The method for constant on-time control of the converter includes setting a switching frequency for the switches Q1 and Q2 to regulate the DC bus voltage, the switching frequency having a corresponding switching period representing a full cycle of both switches Q1 and Q2, modulating the switches Q1 and Q2 180 degrees out of phase between an on-state and an off-state, and switches Q1 and Q2 are kept in the on-state for a fixed time duration that is at most half the switching period, and modulating the switches Q3 and Q4 between the on-state and the off-state, wherein the switch Q3 is in the on-state longer than, and overlapping with, the fixed time duration of switch Q2, and the switch Q4 is in the on-state longer than, and overlapping with, the fixed time duration of switch Q1.

In some embodiments, the method for constant on-time control further comprises generating, from a gate driver, a gate voltage for each of the primary switches Q1-Q4 to transition each of the primary switches between the on-state and the off-state during the switching period, the primary switches entering the on-state upon receiving a high gate voltage and entering the off-state upon receiving a low gate voltage.

In some embodiments, the method for constant on-time control further comprises transmitting, at the start of the switching period, the high gate voltage to the primary switches Q2 and Q3 for a first fixed time duration to transition the primary switches Q2 and Q3 to the on-state.

In some embodiments, the method for constant on-time control further comprises transmitting, upon expiry of the first fixed time duration, the low gate voltage to the primary switch Q2 to transition the primary switch Q2 to the off-state, and maintaining the high gate voltage to the primary switch Q3 until the expiry of half the switching period, transmitting, upon expiry of the first fixed time duration, the high gate voltage to the primary switch Q4 to transition the primary switch Q4 to the on-state, transmitting, at a half point of the switching period, the high gate voltage to the primary switch Q1 for a second fixed time duration to transition the primary switch Q1 to the on-state, transmitting, upon expiry of the second fixed time duration, the low gate voltage to the primary switch Q1 to transition the primary switch Q1 to the off-state, and maintaining the high gate voltage to the primary switch Q4 until expiry of the full switching period; and sensing the DC bus voltage, through a voltage sensor, and modifying the switching frequency of the primary switches based on a delta between the sensed DC bus voltage and a desired DC bus voltage.

In some embodiments, the modified switching frequency is lower than a resonant frequency of the resonant tank.

In some embodiments, the rectifier is one of a voltage multiplier, full-bridge or half-bridge topography.

In some embodiments, the transformer is short-circuited when both primary switches Q3 and Q4 are in the on-state.

In some embodiments, the converter has two transformers coupled in parallel to the input DC voltage, where the primary side of the first transformer is connected to the switching network containing the primary switches Q1-Q4, and the primary side of a second transformer is connected to a second switching network containing primary switches Q5-Q8; and the gate voltage generated by the gate driver for the primary switch Q5 is the same as the gate voltage for the primary switch Q1, the game voltage generated by the gate driver for the primary switch Q6 Is the same as the gate driver voltage generated for the primary switch Q2, the game voltage generated by the gate driver for the primary switch Q7 Is the same as the gate driver voltage generated for the primary switch Q3, and the game voltage generated by the gate driver for the primary switch Q8 Is the same as the gate driver voltage generated for the primary switch Q4.

In some embodiments, the secondary side of the first and second transformers are coupled in series to the resonant tank and the rectifier.

In some embodiments, transitioning the primary switches Q1 and Q2 from the on-state to the off-state occurs after a peak primary side magnetizing current is equal to a switch current, wherein the peak primary side magnetizing current is a measure of current flow across a magnetizing inductor of the transformer multiplied by the turn ratio of the transformer, and the switch current is a measure of current flow across the primary switches Q1 and Q2 when they are in the on-state.

In some embodiments, both primary switches Q1 and Q2 are in the off-state between the expiry of the fixed time duration and the half point of the switching period.

### DESCRIPTION OF THE FIGURES

In the figures, embodiments are illustrated by way of example. It is to be expressly understood that the description and figures are only for the purpose of illustration and as an aid to understanding.

Embodiments will now be described, by way of example only, with reference to the attached figures, wherein in the figures:

FIG. 1 is a circuit diagram for a two-stage power architecture which converts a DC battery voltage to an AC grid output, according to some embodiments.

FIG. 2 is a circuit diagram for a DC-DC converter, with isolation, in a two-stage power architecture which converts a DC battery voltage to an AC grid output, according to some embodiments.

FIG. 3 is a current waveform for a DC-DC converter, with isolation, where the DC battery current is a half sinusoidal waveform, according to some embodiments.

FIG. 4A is a circuit topology for a push-pull LLC converter, according to some embodiments.

FIG. 4B is a circuit topology for a push-pull LLC converter with a parallel inductor, according to some embodiments.

FIG. 5 is a circuit diagram for a push-pull LLC resonant converter with voltage doubler rectifier, according to some embodiments.

FIG. 6A is a gate drive signal for a fixed duty cycle control method, according to some embodiments.

FIG. 6B is a gate drive signal for a fixed duty cycle control method, according to some embodiments.

FIG. 6C is a gate drive signal for a fixed duty cycle control method, according to some embodiments.

FIG. 7A is a gate drive signal for a proposed fixed on-time control method, according to some embodiments.

FIG. 7B is a gate drive signal for a proposed fixed on-time control method, according to some embodiments.

FIG. 7C is a gate drive signal for a proposed fixed on-time control method, according to some embodiments.

FIG. 8A is a diagram of simulated gate drive signals and current waveforms for a push-pull LLC converter under a proposed constant on-time control method, according to some embodiments.

FIG. 8B is a current path diagram within a push-pull LLC converter under a proposed constant on-time control, according to some embodiments.

FIG. 8C is a current path diagram within a push-pull LLC converter under a proposed constant on-time control, according to some embodiments.

FIG. 8D is a current path diagram within a push-pull LLC converter under a proposed constant on-time control, according to some embodiments.

FIG. 8E is a current path diagram within a push-pull LLC converter under a proposed constant on-time control, according to some embodiments.

FIG. 9A is a comparison between a computer simulation and a simplified analysis of a push-pull LLC converter under a proposed constant on-time control, according to some embodiments.

FIG. 9B: is a comparison between a computer simulation and a simplified analysis of a push-pull LLC converter under a proposed constant on-time control, according to some embodiments.

FIG. 9C is a comparison of a resonant tank gain versus ratio of switching frequency (Fs) and resonant frequency (Fr) for a push-pull LLC converter under a proposed constant on-time control, according to some embodiments.

FIG. 10A is a comparison of a peak magnetizing inductor current between a fixed duty cycle control method and a proposed constant on-time control method, according to some embodiments.

FIG. 10B is a comparison of turn off currents of battery side (primary side) switches of a push-pull LLC converter between a fixed duty cycle control method and a proposed constant on-time control method, according to some embodiments.

FIG. 10C is a comparison of a turn-off current ratio for a proposed constant on-time control method and fixed duty cycle control method at below resonant mode, according to some embodiments.

FIG. 11 is a circuit diagram fora push-pull LLC converter with split resonant capacitor and voltage doubler configuration, according to some embodiments.

FIG. 12A is a simulation result for a push-pull LLC converter under fixed duty cycle control when Vb=2.6V, according to some embodiments.

FIG. 12B is a simulation result for a push-pull LLC converter under fixed duty cycle control when Vb=3.7V, according to some embodiments.

FIG. 12C is a simulation result for a push-pull LLC converter under a fixed on-time control method when Vb=2.6V, according to some embodiments.

FIG. 12D is a simulation result for a push-pull LLC converter under a proposed constant on-time control method when Vb=3.7V, according to some embodiments.

FIG. 13 is a circuit diagram for a full-bridge LLC converter with a voltage doubler configuration, according to some embodiments.

FIG. 14 is a circuit diagram for a half-bridge LLC converter with a voltage doubler configuration, according to some embodiments.

FIG. 15A is a gate drive signal for a proposed fixed on-time control method, according to some embodiments.

FIG. 15B is a gate drive signal for a proposed fixed on-time control method, according to some embodiments.

FIG. 16A is a circuit diagram for a two-phase push-pull LLC converter with primary side in parallel and secondary side in series under a proposed constant on-time control, according to some embodiments.

FIG. 16B is a circuit diagram for a multi-phase push-pull LLC converter with primary side in parallel and secondary side in series under a proposed constant on-time control, according to some embodiments.

FIG. 16C is a circuit diagram for a two-phase full-bridge LLC converter with primary side in parallel and secondary side in series under a proposed constant on-time control, according to some embodiments.

FIG. 17 is a circuit diagram of a two-phase push-pull LLC converter operating bidirectionally, according to some embodiments.

FIG. 18 is a control diagram of a push-pull LLC converter under constant on-time control, according to some embodiments.

FIG. 19 is a control diagram of a push-pull LLC converter under constant on-time control, according to some embodiments.

### DETAILED DESCRIPTION

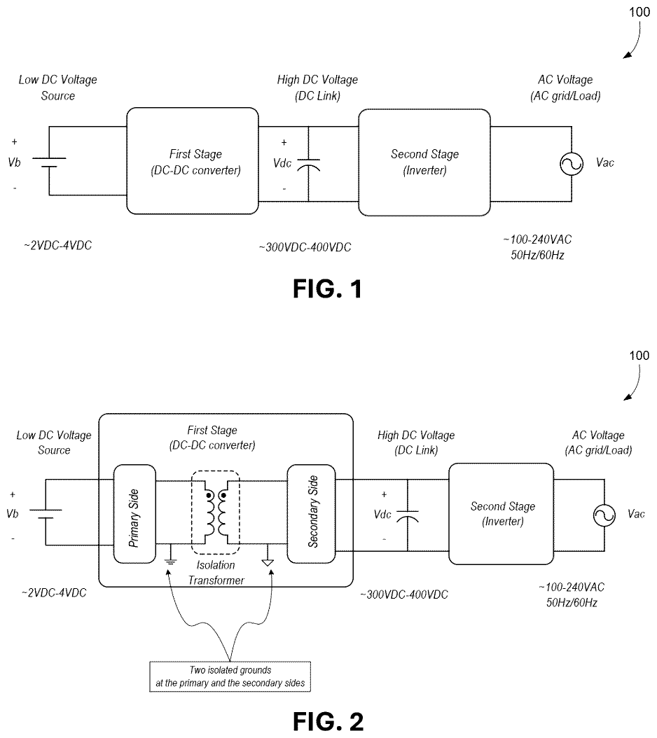

In FIG. 1, a power circuit 100 is shown which converts a lower DC battery voltage into a higher AC grid output voltage. Converting a lower input voltage (such as around 3V) to a higher output voltage (such as 300 to 400V) is commonly performed in power electronics and is an important requirement for battery chargers and dischargers that will typically convert a battery DC (Direct Current) voltage to a higher AC (alternating Current). Circuit 100 is configured to convert the battery voltage (V_{b}) to the grid AC voltage (V_{ac}) through two distinct stages. In the first stage of system 100, the battery voltage Vb is increased to a high DC voltage (V_{dc}), such as 180V to 250V for generating 120V in AC voltage, and 320V to 400V for generating 220V in AC voltage. Then in the second stage of system 100, the DC voltage Vdc is inverted into an AC voltage, such as from 100 to 140V for a 120V AC grid in North America, and from 200V to 240V for a 220V AC grid in Europe, Asia, and other parts of the world. Within the first stage, a high step-up DC-DC converter may be used which is typically either an LLC resonant converter or a push-pull converter. Regardless of whether an LLC resonant converter or a push-pull converter is used, the first stage of system 100 should be configured to have an adequate step-up conversion ratio, voltage isolation, and a single DC-DC converter. For example, since the inverter within the second stage of system 100 requires a minimum DC input voltage Vdc to efficiently output a suitable AC voltage, the DC-DC converter within the first stage of system 100 requires an adequate step-up conversion ratio to generate a high DC output voltage Vdc (DC link voltage) which is then input into the second stage of system 100. Further, since the battery (V_{b}) of system 100 is connected through power circuit 100 to either an AC grid or AC load, it is safer and more reliable to have voltage isolation between the battery (V_{b}) and AC load (V_{ac}) voltage. Voltage isolation may be achieved through a transformer within the high step-up DC-DC converter of the first stage within system 100, as shown in FIG. 2. Accordingly, if a transformer is used within the high step-up DC-DC converter of the first stage within system 100, a single DC-DC converter may be sufficient.

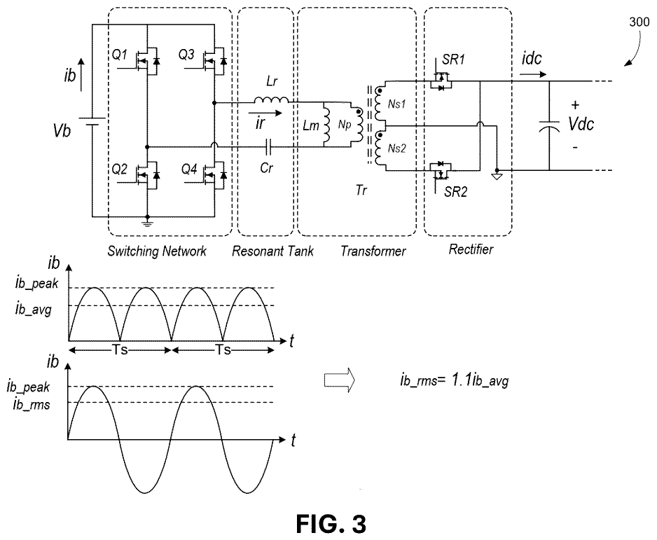

In FIG. 3, a circuit diagram 300 of an alternative LLC resonant converter which may be used as the high step-up DC-DC converter within the first stage of system 100 is shown. Circuit 300 contains a full bridge switching network consisting of four switches Q1, Q2, Q3, and Q4. The switching network of circuit 300 is electrically coupled to a resonant tank consisting of a resonant inductor (Lr) and a resonant capacitor (Cr). A center tapped transformer (Tr) separates circuit 300 into a primary side, comprising the switching network and resonant tank, and a secondary side comprising a rectifier stage which has a pair of synchronous rectifiers (SR1 and SR2). The transformer in this embodiment contains three windings, where the number of turns of the primary winding of transformer Tᵣ is indicated as Np, and the number of turns of the secondary windings of transformer Tᵣ are indicated as Ns1 and Ns2 (Ns1=Ns2). The transformer's magnetizing inductance is shown as Lₘ.

Circuit 300 is an exemplary configuration of an LLC converter, and alternative configurations of the switching network, resonant tank, transformer windings, and rectifier within circuit 300 are possible.

Regardless of the specific configuration of circuit 300, due to the LLC converter being used to step up the battery voltage V_{b}, the primary side of circuit 300 will need to tolerate a high input current (i_{b}). For example, for a desired output power of 300 W, a battery voltage of V_{b}=3V may be stepped up to a DC link voltage of V_{dc}=350V, resulting in the average input current on the primary side of circuit 300 being an average of 100 A (i.e., i_{b_avg}=300 W/3V=100 A), and the average output current on the secondary side of circuit 300 being 0.86 A (i.e., i_{dc}=300 W/350V=0.86 A).

In FIG. 3, the current waveforms under resonant mode operation for the primary side of circuit 300 are shown, and it is evident from the Root-Mean-Square current (i_{b_RMS}) waveform that the resonant tank on the primary side of circuit 300 has to tolerate at least 110 A RMS current. The high input current i_{b_avg}, which flows through the resonant tank, may result in a substantial and undesired conduction power loss (as conduction loss is proportional to the squared value of the input current), and may require bulky and costly inductors and capacitors that are rated for the high input current i_{b_avg}. Further, due to circuit 300 having a full bridge switching network, the conduction losses are doubled compared to a half bridge switching network containing two switches. As shown in the current waveforms of FIG. 3, the i_{b_RMS} present in the resonant tank in circuit 300 will be at least 10% more than the average current (i_{b_avg}) on the primary side of circuit 300 (i_{b_rms}=1.1i_{b_avg}=110 A) due to the relationship between the rms value and the average value of a sinusoidal waveform. Therefore, not only will the conduction losses be substantial, but the current stress experienced by the resonant tank components will also increase. Accordingly, it may be desirable to place the resonant tank (Lr, Cr) on the secondary side of circuit 300 to reduce the current stress experienced by the resonant tank, and accordingly reduce the current rating requirements of the resonant tank components.

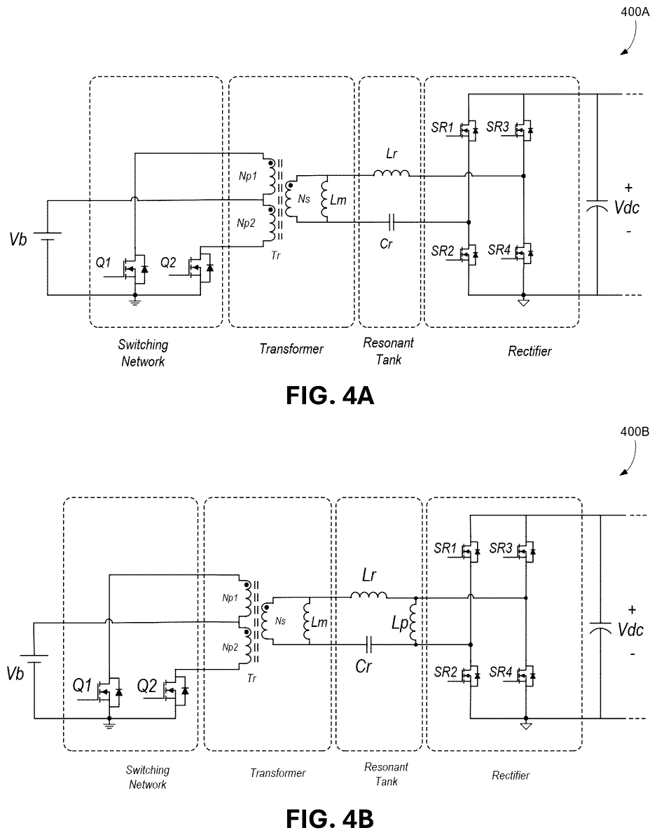

In FIG. 4A, a circuit diagram 400A of a proposed push-pull LLC resonant converter which may be used as the high step-up DC-DC converter within the first stage in system 100 is shown. Circuit 400A combines a ground referenced dual switch topology of a push-pull converter on the primary side of transformer Tᵣ with a resonant tank and full bridge switching network (acting as a rectifier) topology of an LLC converter on the secondary side of transformer Tᵣ.

As seen in FIG. 4A, circuit 400A contains a switching network comprising a half bridge switching network consisting of two switches Q1, Q2. The switching network is electrically coupled to a center tapped transformer (Tr), and each of switch Q1 and Q2 is in series with a corresponding primary winding of transformer Tᵣ. The transformer Tᵣ in this embodiment contains three windings (i.e., two primary, and one secondary), where the number of turns of the primary windings of transformer Tᵣ are indicated as Nₚ₁ and Nₚ₂, and the number of turns of the secondary winding of transformer Tᵣ is indicated as Nₛ. The magnetizing inductance of transformer Tr is shown as Lₘ. On the secondary side of circuit 400A, a resonant tank, consisting of a resonant inductor (Lr) and a resonant capacitor (Cr), is coupled in series with the secondary winding of transformer Tᵣ. The resonant tank is electrically coupled to a full bridge rectifier consisting of four switches (SR1, SR2, SR3 and SR4), however, in other embodiments, the rectifier of circuit 400A may include alternative rectifier structures such as a voltage doubler. Therefore, the resonant network and rectifier on the secondary side of circuit 400A is electrically isolated from the switching network by transformer Tᵣ.

Compared to circuit 300, the resonant tank in circuit 400A is isolated, on the secondary side, from the high input current i_{b}, which may reduce the current stress on the resonant tank components in circuit 400A. Further, the switching network of circuit 400A may have reduced conduction losses, compared to circuit 300, due to the switching network on the primary side of circuit 400A having two switches (Q1, Q2) compared to the four switches in circuit 300.

Circuit 400A is configured such that the switches Q1 and Q2 can be turned on when their voltages are zero to achieve the desired Zero-Voltage turn-on operation when operating at resonant mode (i.e., minimal to no impedance from resonant tank), which eliminates turn-on losses.

In circuit 400A, the output voltage V_{dc} can be regulated by controlling the switching frequency of switches Q1 and Q2 while the duty cycle remains constant. Meaning that when the switching frequency Fs is equal to the resonant frequency Fᵣ (at resonant mode, i.e. Fs=Fr), the voltage gain M is at its maximum (“N”), and it is therefore equal to M=V_{dc}/V_{b}=N. For circuit 400A, the resonant frequency is defined as:

$${F}_{r} = \frac{1}{2 π \sqrt{{L}_{r} {C}_{r}}} \qquad ( 1 )$$

However, when the switching frequency Fs is higher than the resonant frequency Fr (above resonant mode, i.e. Fs>Fr), the voltage gain is lower than “N”, because the resonant tank inductor Lr and capacitor Cr become inductive and form a voltage divider with the Lm (the magnetizing inductance), which lowers the voltage gain.

Further, when the switching frequency Fs is lower than the resonant frequency Fr (below resonant mode, i.e. Fs<Fr), the voltage gain M remains almost constant due to the resonant and magnetic characteristics of the circuit. Therefore, in order to control the voltage gain M of circuit 400A to regulate the output voltage V_{dc}, circuit 400A has to operate at above resonant mode, as the voltage gain is almost constant when the switching frequency is below the resonant frequency. However, operating at above resonant mode means the current waveform does not reach zero before the switches Q1, Q2 turn off. The switches Q1, Q2 are forced to turn off while the resonant current is still large, leading to high turn-off current and significant switching losses of switches Q1, Q2. Consequently, circuit 400A may experience undesirable losses when regulating the output voltage V_{dc} outside of the maximum voltage gain M.

In alternative embodiments, to address the inability of circuit 400A to regulate voltage at below resonant mode, an additional inductor Lₚ is integrated into the secondary side of a push-pull LLC converter as shown in circuit 400B of FIG. 4B. Inductor Lₚ is in parallel with the resonant tank of circuit 400B, and is coupled between the rectifier and the resonant components (resonant inductor Lᵣ and resonant capacitor Cᵣ) of the resonant tank. In some embodiments, the inductance of inductor Lₚ is about equal to the inductance of the magnetizing inductor Lₘ of the transformer (Lm=Lp). In this condition, circuit 400B may regulate output voltage V_{dc} under light load at a switching frequency below resonant frequency, which additionally reduces switching loss. However, the issue of high turn-off current is still present. Further, compared to circuit 400A, the additional component required for circuit 400B may increase the cost of the circuit and increase the power loss due to copper and core losses.

Therefore, circuits 400A and 400B may be preferred over circuit 300, due to their reduced switching and conduction losses, for usage as a high step-up DC-DC converter within system 100. However, as discussed above, circuits 400A and 400B still experience undesirable losses when used as a high step-up DC-DC converter under variable switching frequency—constant duty cycle control, which may impact the performance and cost of system 100. For example, circuit 400A must be operated at above resonant mode in order to regulate the output voltage Vdc, resulting in high turn-off current and switching frequency for switches Q1, Q2 which may increase the associated switching losses. Circuit 400B incorporates an additional inductor Lₚ, which may reduce the switching losses compared to circuit 400A, but the additional inductor Lₚ results in additional costs and power losses within system 100.

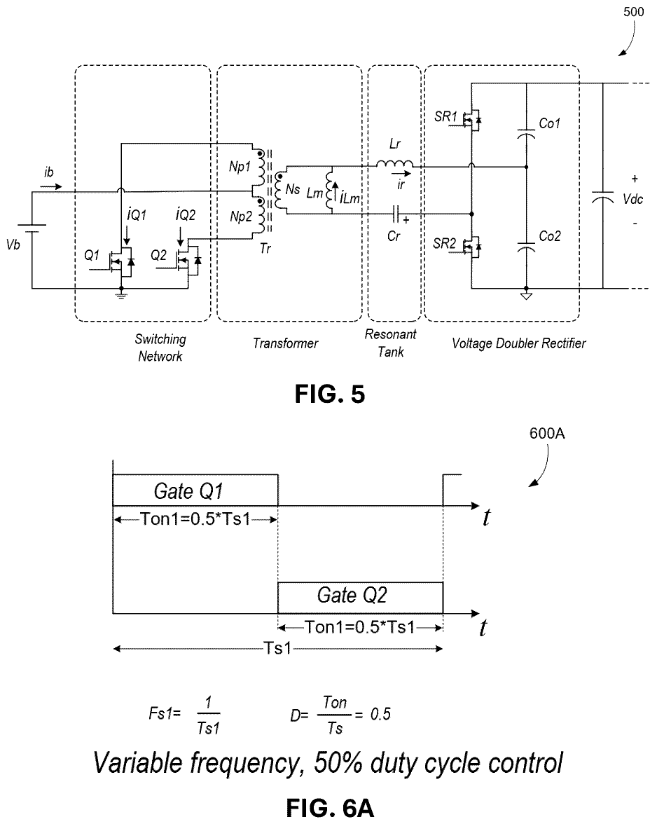

In FIG. 5, a circuit diagram is shown of circuit 500 operating under a proposed control method that uses constant on-time for the switches Q1 and Q2. As discussed further below, the proposed constant on-time control method may enable circuit 500 to achieve voltage regulation at below resonant mode, resulting in lower switching losses. Further, as the reduced switching losses in circuit 500 under the proposed constant on-time control method does not require additional component(s) to be added into circuit 500 (i.e., such as additional inductor Lp in circuit 400B), the reduction in switching losses discussed below do not generate a corresponding increase in cost and power loss due to the additional component(s).

In FIG. 5, the topology in circuit 500 is substantively the same as circuit 400A shown in FIG. 4A, with the exception that the full bridge rectifier of circuit 400A has been replaced with a voltage doubler rectifier in circuit 500.

In FIG. 5, Q1 and Q2 each have a corresponding on-time (Tₒₙ). According to the proposed constant on-time control method for circuit 500, the on-time of Q1 and Q2 (Tₒₙ) remains the same under varying switching frequencies FS, while the switching period (Tₛ) of Q1 and Q2 is modulated to generate a desired voltage gain (M) in circuit 500, and accordingly regulate the output voltage V_{dc}. Embodiments of the proposed constant on-time control method may have the technical benefits of reducing the components required on the primary side of transformer Tᵣ, broad output voltage Vdc regulation at below resonant mode, minimizing turn-off current and soft switching at turn-on for switches Q1 and Q2, reducing the turn ratio of the transformer Tr, and bidirectional operation.

For example, when applying constant on-time control to circuit 500 for improved output voltage Vdc regulation, the primary side of circuit 500 only requires two switches Q1, Q2 and two transformer windings Np1, Np2, such that conduction losses and switching losses are minimized on the primary side of circuit 500. Further, as constant on-time control may enable output voltage Vdc regulation at below resonant mode in circuit 500, additional components, such as additional inductor Lp in circuit 400B, may be omitted.

In some embodiments, constant on-time control may reduce the turn-on and turn-off current for switches Q1 and Q2, resulting in reduced turn-on and turn-off power loss within circuit 500. This is achieved by selecting the on-time of switches Q1, Q2 to be very close to half the resonant period of the resonant tank formed by Lr and Cr. Consequently, switches Q1 and Q2 are turned off at the instance when the resonant current iLr falls to zero. Since the turn off current of switches Q1 and Q2 is essentially the magnetizing current iLm through the magnetizing inductor Lm, which is much smaller than the peak resonant current. This significantly reduces turn-off losses. Similarly, at turn-on time of switches Q1 and Q2, the resonant current iLr starts from zero, therefore the turn-on current is also essentially the magnetizing current iLm. This enables Zero-Current Switching (ZCS) at turn-on, which is a form of soft switching, thus minimizing switching losses and stress on the system.

In some embodiments, the rectifier on the secondary side of circuit 500 may operate as a voltage multiplier, for example, a voltage doubler. By incorporating a voltage multiplier rectification stage, the responsibility of voltage amplification is shared between both the transformer Tr (i.e., through it's turn ratio) and the rectifier stage. As a result, the turn ratio of transformer Tr is reduced, and accordingly, the power loss, size and cost of transformer Tr is reduced.

In circuit 500 shown in FIG. 5, a voltage doubler rectifier is used for the rectifier stage. The effect of the voltage doubler on the voltage gain, shown below in equation (9), causes the resonant tank gain (Mr) and transformer gain (N) to be doubled, resulting in a reduction in the turn ratio required for the transformer Tr. In another embodiment, shown in converter circuit 500-1 in FIG. 11, a split resonant capacitor topology for the resonant tank can be incorporated with the voltage doubler rectifier. The split resonant capacitor topology in circuit 500-1 contains two split resonant capacitors Cr1 and Cr2, which replace the single resonant capacitor Cr. The capacitance value of the two split resonant capacitors Cr1 and Cr2 may be half of the capacitance value of the single resonant capacitor Cr in circuit 500 (i.e., Cr1=Cr2=Cr/2). A split capacitor version of the resonant tank may be preferred over a single capacitor version because it allows the use of one electrolytic capacitor instead of two. This design can simplify the circuit and reduce cost and size, while still maintaining the required capacitance.

Regardless of whether the converter has a resonant tank topology with a single resonant capacitor, such as in 500, or a split resonant capacitor, such as in 500-1, the proposed constant on-time control method and the associated benefits to, for example, voltage regulation and turn-off current losses, can still be achieved.

A further benefit of circuit 500 is that due to the usage of active switches (i.e. MOSFETs, IGBTs, etc.) as the synchronous rectifiers SR1 and SR2, circuit 500 can operate bidirectionally for voltage regulation. For example, when circuit 500 transfers power from the low voltage side (i.e., Vb) to the high voltage side (i.e., Vdc), switches Q1 and Q2 are the primary switches and SR1 and SR2 operate as synchronous rectifiers. However, when circuit 500 transfers power from the high voltage side (Vdc) to the low voltage side (Vb), SR1 and SR2 may act as the primary switches and switches Q1 and Q2 may operate as synchronous rectifiers. Therefore, when circuit 500 transfers power from the high voltage side to the low voltage side, circuit 500 can operate as an LLC resonant converter which regulates the low side voltage (Vb) with variable frequency control methods such as the proposed constant on-time control method.

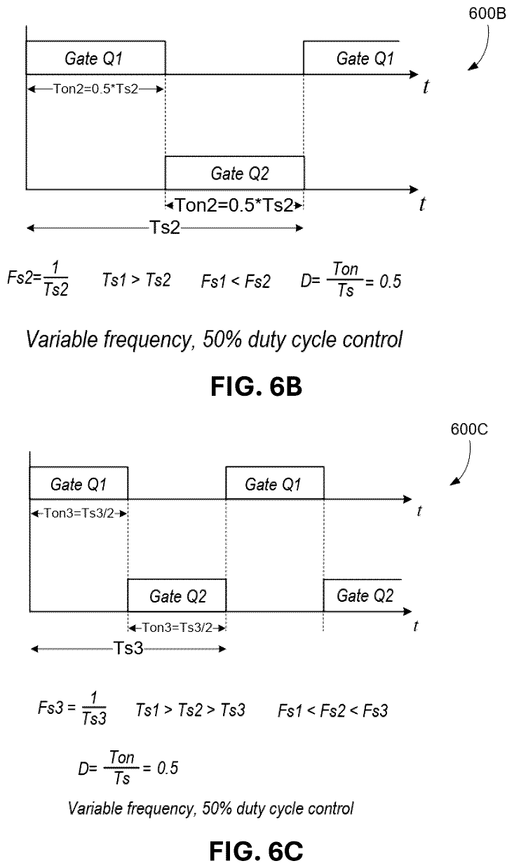

In FIGS. 6A, 6B and 6C, alternative control methods 600A, 600B and 600C for voltage regulation are shown for switches Q1 and Q2 in circuits 400A, 400B and 500.

According to alternative control methods 600A, 600B and 600C, a switching frequency Fs, and an associated switching period Ts, is applied while the duty cycle of switches Q1 and Q2 are kept constant at 50%. In each of alternative control methods 600A, 600B and 600C, the switching period Ts1 (600A), Ts2 (600B) and Ts3 (600C) incrementally reduces in duration such that Ts1>Ts2>Ts3. Therefore, as the duty cycle for switches Q1 and Q2 are kept constant at 50%, the on-time (Ton), equal to the product of the duty cycle (50%) and switching period (Ts), for both Q1 (Ton1) and Q2 (Ton2) varies depending on the duration of the switching period. As can be seen by comparing the on-time (Ton) in control methods 600A, 600B, and 600C for switches Q1 and Q2, when the switching frequency is lower, Ton for Q1 and Q2 is longer since Ton is maintained at half of the switching period (i.e., 0.5*Ts1>0.5*Ts2>0.5*Ts3).

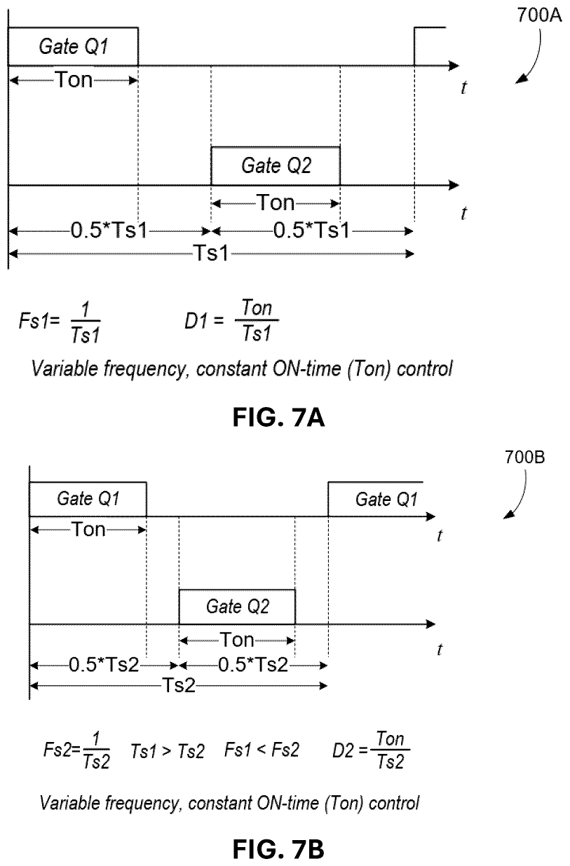

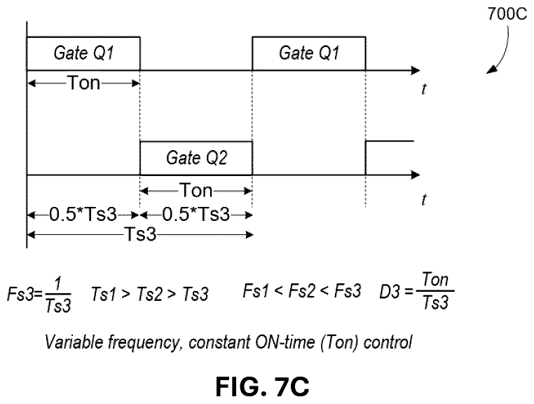

In FIGS. 7A, 7B and 7C, embodiments of a proposed constant on-time control method 700A, 700B and 700C for switches Q1 and Q2 of circuit 400A, 400B and 500 are shown. The gate drive signals of switches Q1 and Q2 are shown in FIGS. 7A, 7B, and 7C under three different switching frequencies (Fs1, Fs2, Fs3). In control methods 700A (FIG. 7A), 700B (FIG. 7B) and 700C (FIG. 7C), the on-time of both switches Q1 and Q2 is held constant, while the switching frequency (Fs1, Fs2, Fs3), and associated switching period (Ts1, Ts2, Ts3), is varied to regulate the output voltage. Therefore, the duty cycle (D1, D2, D3) of switches Q1 and Q2 in control methods 700A, 700B and 700C varies depending on the duration of the switching period (Ts).

Comparing the switching frequency Fs in FIGS. 7A, 7B and 7C, the switching frequency Fs1 in 700A is the lowest and the switching frequency Fs3 in 700C is the highest, with switching period Fs2 in 700B being between Fs1 and Fs3. Therefore, switching period Ts1 in 700A is the longest in duration, switching period Ts3 in 700C is the shortest in duration, and switching period Ts2 in 700B is between Ts1 and Ts3.

Since the on-time (Ton) of switches Q1 and Q2 is held constant across 700A, 700B and 700C, as the switching period (Ts1, Ts2, Ts3) decreases, the duty cycle (D1, D2, D3) of Q1 and Q2 increases (i.e., Ts1>Ts2>Ts3; D1<D2<D3).

Further, as the on-time (Ton) of switches Q1 and Q2 in control methods 700A, 700B and 700C is held constant, voltage gain M will increase as the switching frequency Fs increases (and switching period Ts decreases). Therefore, since Fs1<Fs2<Fs3 (and Ts3<Ts2<Ts1), voltage gain M is highest in 700C and lowest in 700A. For example, in control method 700A, the switching frequency Fs1 is lower compared to Fs2 and Fs3 in control methods 700B and 700C, and due to the on-time Ton of Q1 and Q2 being held constant across control methods 700A-700C, the duty cycle of switches Q1 and Q2 in 700A is about 33%. As the switching frequency Fs increases, such as from Fs1 in 700A to Fs3 in 700C, but the on-time Ton of switches Q1 and Q2 remains constant, the duty cycle increases from about 33% in 700A to about 50% in 700C. Therefore, according to the proposed constant on-time control method, as switching frequency Fs increases (and switching period Ts decreases), the duty cycle of switches Q1 and Q2 increases. However, once the duty cycle reaches about 50%, such as in 700C, any further increases in switching frequency Fs (or decreases in switching period Ts), will cause the on-time of switches Q1 and Q2 to overlap, and result in a short circuit at the input source Vb. This operational condition should be avoided.

It is noted from FIGS. 7A, 7B, 7C, that the relationship between the gate drive signals of switches Q1 and Q2 is about 180-degrees out of phase. In other words, they are phase-shifted by 180 degrees from each other. In addition, the on-time of switches Q1 and Q2 is at most half the switching period. The on-time is always less than or equal to half of the switching period. As mentioned above, the on-time is selected to be very close to half of the resonant period of the resonant tank to reduce the power loss.

According to the proposed constant on-time control method shown in FIGS. 7A, 7B and 7C, the turn off current for switches Q1 and Q2 is essentially equal to the magnetizing current iLm, which is much lower than the resonant current iLr. Since only a small amount of resonant energy (zero in the ideal case) is sent back to the input voltage (battery), the conduction loss is minimal. This contrasts with the alternative 50% duty cycle control method, in which the turn off current of switches Q1, Q2, is the resonant current iLr, which is much higher than the magnetizing current iLm, leading to higher switching losses and unnecessary energy circulation back to the source.

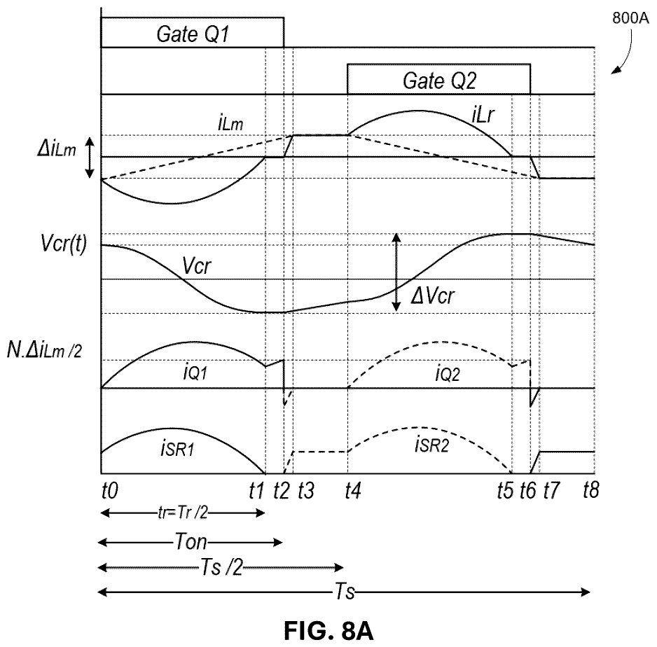

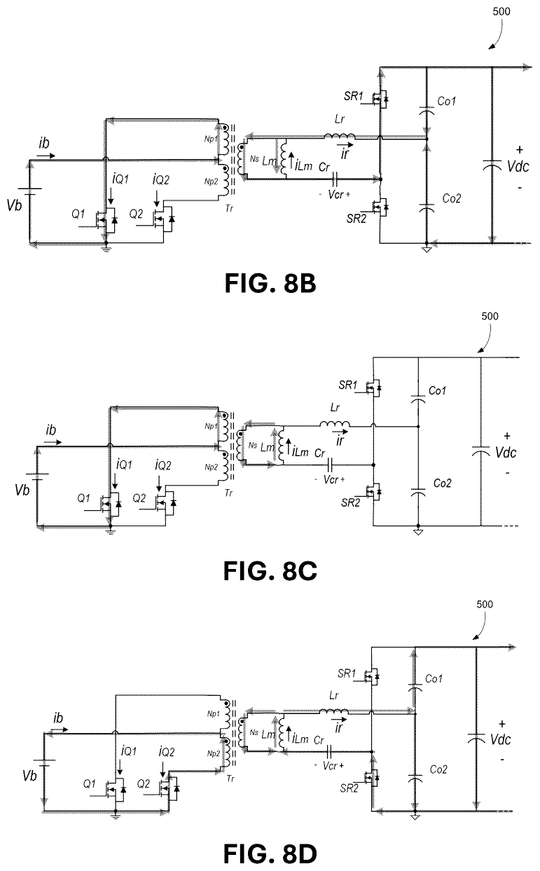

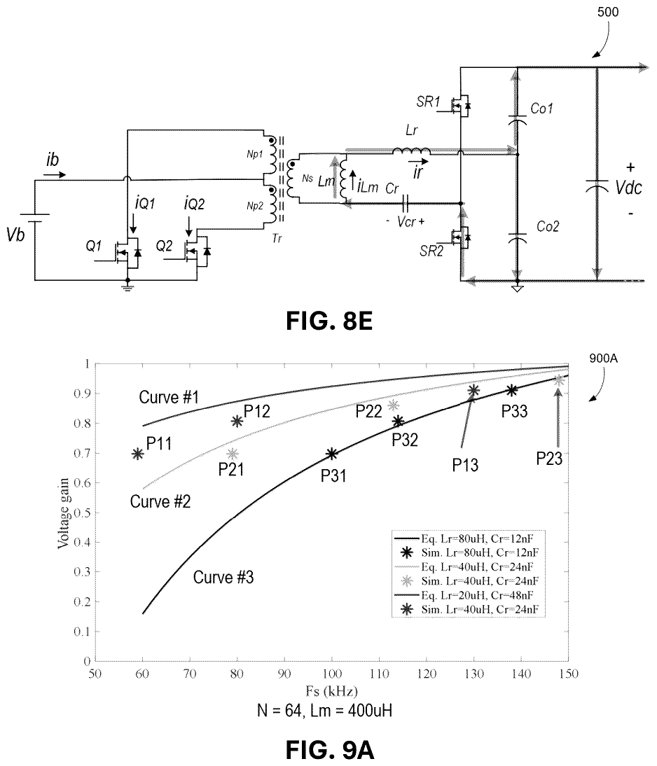

In FIG. 8A, gate drive signals for switches Q1, Q2, and the resulting current and voltage waveforms 800A of circuit 500 are shown for one switching period Ts under constant on-time control. In FIG. 8A, switching period Ts is divided into eight intervals from t0 to t8.

The current path through circuit 500 for interval 1 is shown in FIG. 8B. Interval 1 in FIG. 8A [t0 to t1] begins at t0, when switch Q1 is turned ON. At t0, the current across switch Q1 (switch current iQ1) begins at zero and starts to rise, meaning that switch Q1 turns ON at ZCS condition. When Q1 is ON, the input current ib flows from the primary winding Np1 to the secondary winding Ns of transformer Tr, and is applied to the magnetizing inductor Lm. Therefore, the magnetizing current iLm across the magnetizing inductor Lm will increase. Meanwhile, the resonant tank of circuit 500 starts to resonate. The resonant current iLr flows through synchronous rectifier SR1 and then splits in half and flows through one of the output capacitors (Co1 and Co2). The resonant current iLr reaches zero at t1 and this interval ends. Since the resonant current iLr gradually goes to zero, synchronous rectifier SR1 turns OFF at ZCS condition. Meaning that there is no reverse recovery loss for synchronous rectifier SR1.

The current path through circuit 500 for interval 2 is shown in FIG. 8C. Interval 2 in FIG. 8A [t1 to t2] begins at t1 when the resonant current iLr is zero, and the switch current iQ1 on the primary side of transformer Tr is equal to the magnetizing current iLm multiplied by the turn ratio of transformer Tr (iQ1=N×iLm, N=Ns/Np1, Np1=Np2). Interval 2 ends at t2, when switch Q1 is turned OFF. As previously explained, the magnetizing current iLm is much smaller than the resonant current iLr and therefore, the turn off current of Q1, Q2 is much smaller, as compared to alternative control methods.

The current paths through circuit 500 for interval 3 is shown in FIG. 8D. Interval 3 of FIG. 8A [t2 to t3] begins at t2, when switch Q1 transitions to the off state, the resonant current iLr is still zero. The difference between the resonant current iLr and magnetizing current iLm flows through the windings of transformer Tr. Since the switches Q1 and Q2 at the primary side of circuit 500 are both OFF, the input current ib flows through the body diode of switch Q2. As the resonant tank current iLr rises in the negative direction, the synchronous rectifier SR2 of the rectifier stage starts conducting. At t3, the resonant current iLr and magnetizing current iLm become equal, and the current across the primary windings of the transformer Tr becomes zero.

The current paths through circuit 500 for interval 4 are shown in FIG. 8E. Interval 4 of FIG. 8A [t3 to t4] begins at t3 in which the resonant tank current iLr and magnetizing current iLm are equal, and the resonant tank current iLr flows through synchronous rectifier SR2 within the rectifier stage. Interval 4 ends at t4 when Q2 turns ON.

Interval 5 (t4 to t5], interval 6 [t5 to t6], interval 7 [t6 to t7] and interval 8 [t7 to t8] are substantively identical to the first four intervals defined above, with the only difference being that Q1 is OFF and Q2 is turned ON, and the direction of resonant current iLr and magnetizing current iLm are reversed (i.e., since the waveforms are symmetrical in a half switching period).

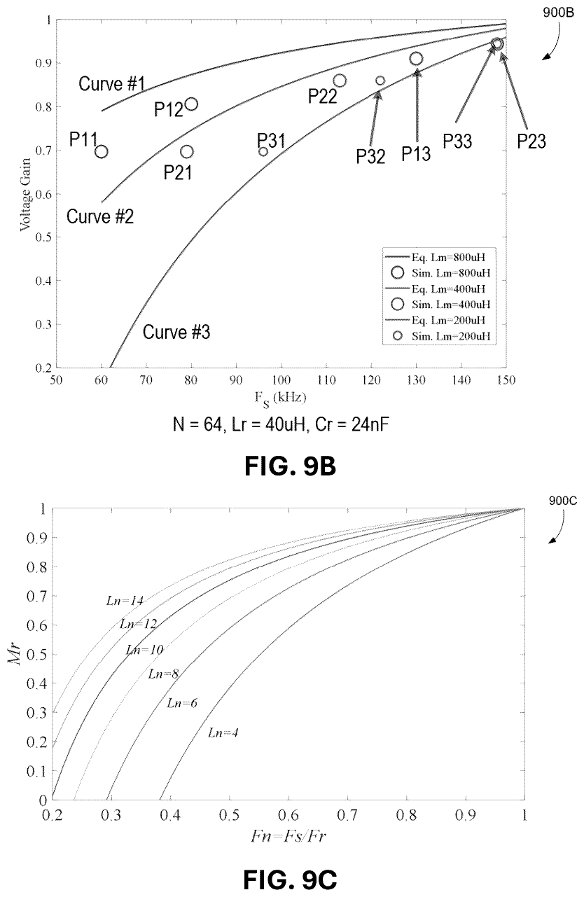

A time domain analysis was performed of the voltage regulation properties of the proposed constant on-time (Ton) control method, and the results show below were compared with simulation results in FIG. 9A-9B. Reference is made to the intervals 1 through 8 shown in FIG. 8A.

In Interval 1 [t0 to t1] shown in FIG. 8A, the resonant current iLr can be represented as:

$$iLr ( t ) = \frac{N \cdot Vb + Vcr ( t 0 ) - \frac{Vo}{2}}{\sqrt{\frac{Lr}{Cr}}} sin ( ω r \cdot t ) \qquad ( 2 )$$

where V_{cr}(t0) is the resonant capacitor voltage at t0, and ωr is the resonant angular frequency defined as 1/√LᵣCᵣ. It is assumed that the resonant current starts from zero.

The resonant capacitor voltage V_{Cr} at t0 can be calculated as:

$${V}_{Cr} ( {t}_{0} ) = \frac{Δ {V}_{Cr}}{2} - \frac{Δ {i}_{Lm}}{2 {C}_{r}} ( \frac{{T}_{S}}{2} - {T}_{ON} ) \qquad ( 3 )$$

where ΔVcr is the peak-to-peak voltage variation of the resonant capacitor Cᵣ, ΔiLm is the peak-to-peak variation of the magnetizing inductor's current I_{Lm}. ΔVcr can be calculated as:

$$Δ Vcr = \frac{1}{Cr} {\int }_{t 0}^{t 1} iLr ( t ) dt + \frac{Δ iLm}{2 Cr} ( \frac{Ts}{2} - Ton ) \qquad ( 4 )$$

Further, the integral part in equation (5) below can be calculated using equation (4) to determine the numerical expression for the voltage ripple of resonant capacitor:

$$\frac{1}{Cr} {\int }_{t 0}^{t 1} iLr ( t ) dt = 2 \frac{N \cdot Vb + Vcr ( t 0 ) - \frac{Vo}{2}}{ω r \cdot Cr \cdot \sqrt{\frac{Lr}{Cr}}} = 2 ( N \cdot Vb + Vcr ( t 0 ) - \frac{Vo}{2} ) \qquad ( 5 )$$

It is assumed that Ton of switches Q1 and Q2 are equal to the duration of interval 1 [t0 to t1] which is equal to half of the resonant period Tr (interval 2 is neglected):

$$Ton = t 1 - t 0 = \frac{Tr}{2} = π \sqrt{LrCr} \qquad ( 6 )$$

According to FIG. 8A, the input voltage Vb is applied to the magnetizing inductor Lₘ when either of switches Q1 or Q2 are in the ON-state (i.e., during Ton of Q1 or Q2), and when both switches Q1 and Q2 are in OFF-state, the magnetizing inductor current i_{Lm} is substantially constant. So, ΔiLm can be calculated as:

$$Δ iLm = \frac{N \cdot Vb \cdot Ton}{Lm} \qquad ( 7 )$$

Now incorporating equations (4), (5), and (7) into equation (3) produces:

$$Vcr ( t 0 ) = N \cdot Vb + Vcr ( t 0 ) - \frac{Vo}{2} - \frac{N \cdot Vb \cdot Ton}{4 Cr \cdot Lm} ( \frac{Ts}{2} - Ton ) \qquad ( 8 )$$

In equation (8), Vcr(t0) at both sides of the equation cancel each other out, so the voltage gain M will be:

$$M = \frac{Vo}{Vb} = 2 N ( 1 - \frac{Ts \cdot Ton}{4 Lm \cdot Cr} ( \frac{1}{2} - \frac{Ton}{Ts} ) ) = 2 N \cdot Mr \qquad ( 9 )$$

This voltage gain M is dependent on three factors 1) Mᵣ is the resonant tank gain, 2) N is the transformer gain, and 3) the whole voltage gain is doubled as a result of the voltage doubler rectifier stage in circuit 500.

This voltage gain is validated by comparing equation (9) with simulations shown in FIGS. 9A-9B. In FIG. 9A, the results are shown for a simulation 900A of circuit 500 under the proposed constant on-time control method, where the transformer gain (N) is 64, and the magnetizing inductance (Lm) is 400 uH. The resonant inductance Lr and capacitance Cr were varied during simulation 900A, and the values for Lr and Cr are shown in the legend of FIG. 9A. The resonant frequency Fr was kept constant at all conditions and is equal to 150 kHz.

In FIG. 9B, results are shown for a simulation 900B of circuit 500 under the proposed constant on-time control method, where the transformer gain (N) is 64 and the resonant inductance Lr and capacitance Cr values are fixed at 40 uH and 24 nF, respectively. The magnetizing inductance Lm was varied during simulation 900B, and the values for Lm can be seen in the legend in FIG. 9B.

As can be seen from comparing the results from simulation 900A and 900B with the expected results based on equation (9), the difference between simulations 900A, 900B and equation (9) is less than 10%, which is likely a result of the simplifications and assumptions that were made during for simulations 900A, 900B. Therefore, simulations 900A, 900B provide support and validation of the theoretical analysis performed above.

According to equation (6) and (9), and considering that resonant frequency Fr=½π\sqrt{LrCr}, Mᵣ can be rewritten as:

$$Mr = ( 1 - \frac{Ts \cdot Tr}{16 Lm \cdot Cr} ( 1 - \frac{Tr}{Ts} ) ) = ( 1 - \frac{{π}^{2}}{4} \frac{Lr}{Lm} ( \frac{Fr}{Fs} - 1 ) ) = ( 1 - \frac{{π}^{2}}{4} \frac{1}{Ln} ( \frac{1}{Fn} - 1 ) ) \qquad ( 10 )$$

where Ln is the magnetizing inductance to resonant inductance ratio (Ln=Lm/Lr), and Fn is the switching frequency to resonant frequency ratio (Fn=Fs/Fr).

In FIG. 9C, results 900C show how resonant tank gain (Mr) changes in respect of Fn and Ln. Since in a converter such as circuit 500, the ratio of magnetizing inductance to resonant inductance (Ln) and transformer gain (N) are fixed based on component selection, the output voltage Vdc may be regulated through controlling the ratio of switching frequency to resonant frequency (Fn).

Further, as seen in FIG. 9C, voltage regulation using the proposed constant on-time control method is possible at below resonant mode (Fs<Fr, or Fn<1). For example, if Ln=6, the output voltage gain can be changed from 1 when Fn=1, or Fs=Fr, to zero when Fn is close to 0.3, or Fs=0.3 Fr. Therefore, a lower switching frequency (Fr) may be used for circuit 500 and the switching losses from switches Q1 and Q2 may be reduced compared to alternative approaches, such as constant duty cycle control, which require operating at or above resonant mode.

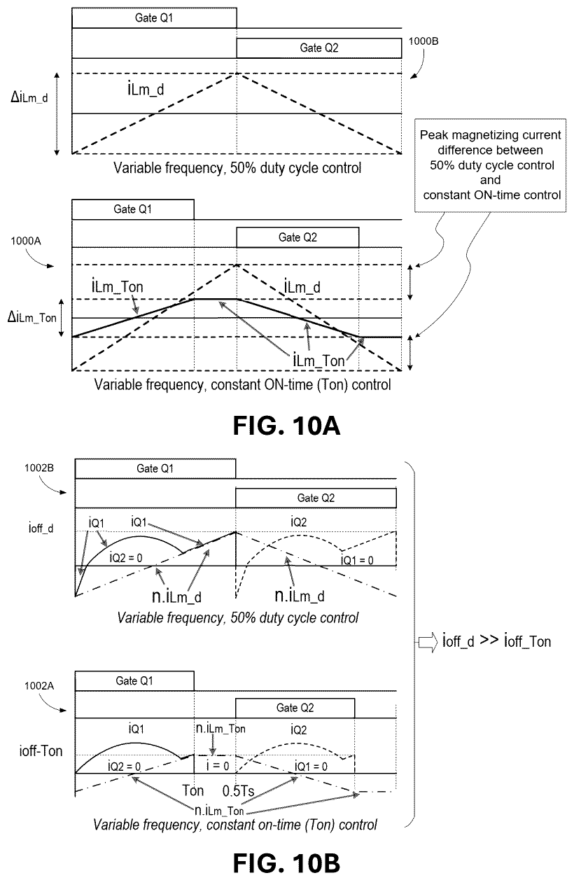

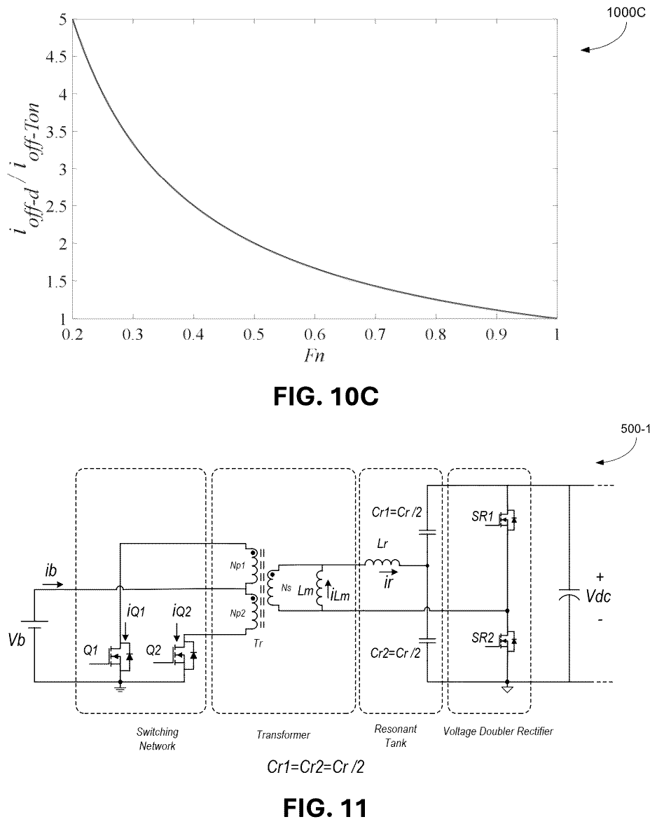

FIG. 10A shows waveform diagrams 1000A and 1000B for the magnetizing currents iLm for both the constant on-time control method (1000A) and an alternative approach using constant 50% duty cycle (1000B). By comparing the peak magnetizing currents iLm at the same switching frequency Fs for both the constant on-time control method (1000A) and an alternative approach using 50% duty cycle (1000B), it can be seen that the peak magnetizing current iLm in 1000B is higher than the peak magnetizing current iLm in 1000A at the time that switch Q1 is turned off, and at the time that switch Q2 is turned on.

In waveform diagram 1000A, the magnetizing current waveform iLm_Ton under variable frequency is shown for the proposed constant ON-time control method, and ΔiLm_Ton is the peak-to-peak variation of iLm_Ton.

As discussed above, for the proposed constant on-time control method, the magnetizing current iLm shown in waveform 1000A changes only during the on-time (Ton) of either switches Q1 or Q2. When both switches Q1 and Q2 are off, the voltage across the windings of transformer Tr is zero and therefore, the magnetizing current iLm does not change. Since Ton is fixed, the peak magnetizing current iLm is also fixed, and it does not change with the switching frequency Fs. Consequently, the turn-off current of the switches Q1 and Q2 remains constant even as the switching frequency Fs changes.

Therefore, the proposed constant on-time control method may reduce the turn-off current of switches Q1 and Q2, resulting in a reduction in the switching losses at turn-off due to switching happening at a lower magnetizing current i_{Lm} than in alternative control approaches. For example, under constant on-time control, the turn-off current of the primary switches Q1 and Q2 for below resonant mode operation is equal to the peak magnetizing current i_{Lm} multiplied by the turn ratio of the transformer Tr.

In the waveform diagram 1000B, the magnetizing current (iLm_d) under variable frequency is shown for an alternative control approach using a 50% duty cycle, and ΔiLm_d is the peak-to-peak variation of iLm_d.

Under alternative switching frequency control approaches, such as the 50% duty cycle shown in waveform diagram 1000B, the peak magnetizing current iLm changes with the switching frequency Fs. This can be attributed to Ton of Q1 and Q2 increasing when the switching frequency decreases.

In FIG. 10B, the waveform diagrams 1002A and 1002B are shown, along with a comparison of the turn-off current i_{off} of the switches Q1 and Q2 for the constant on-time control method (1002A) and an alternative approach using 50% duty cycle (1002B) at the same switching frequency Fs.

When using the alternative control approach (i.e., 50% duty cycle) under variable frequency shown in 1002B, the turn-off current i_{off_d} for switches Q1 and Q2 is equal to:

$$ioff\_d = N \frac{Δ iLm\_d}{2} = \frac{{N}^{2} \cdot Vb \cdot Ts / 2}{2 Lm} = \frac{{N}^{2} \cdot Vb}{4 Fs \cdot Lm} \qquad ( 11 )$$

where ioff_d is the turn-off current of the switches Q1 and Q2 under constant duty cycle control (i.e., 50% duty cycle).

When using the proposed constant on-time control under variable frequency shown in 1002A, the turn-off current i_{off_Ton} for switches Q1 and Q2 is equal to:

$$ioff\_Ton = N \frac{Δ iLm}{2} = \frac{{N}^{2} \cdot Vb \cdot Ton}{2 Lm} = \frac{{N}^{2} \cdot Vb \cdot π \sqrt{LrCr}}{2 Lm} = \frac{{N}^{2} \cdot Vb}{4 Fr \cdot Lm} \qquad ( 12 )$$

where ioff-Ton is the turn-off current of the switches Q1 and Q2 in constant ON-time control.

When operating below the resonant mode, since the switches Q1 and Q2 under the alternative control approach shown in 1002B remain in the on-state for a longer duration of time compared to the proposed constant on-time control method shown in 1002A, the turn-off current i_{off} for the alternative control approach (i.e., 50% duty cycle) will be higher (i.e., i_{off_d}>i_{off_Ton}).

FIG. 10C shows a graphical representation 1000C of the turn-off current ratio CR between the constant on-time control method and an alternative approach using 50% duty cycle at below resonant mode.

The turn-off current ratio (CR) is:

$$CR = \frac{ioff\_d}{ioff\_Ton} = \frac{Fr}{Fs} = \frac{1}{Fn} \qquad ( 15 )$$

As seen in 1000C, as switching frequency Fs reduces, the turn-off current i_{off_Ton} for the constant on-time control becomes much smaller than the turn-off current i_{off_d} for the alternative switching frequency control (i.e., 50% duty cycle). Therefore, under the proposed constant on-time control, the switching loss at turn-off for switches Q1 and Q2 will be reduced, improving the efficiency of converters such as circuit 500 when operating at below resonant mode.

The constant ON-time control method can therefore efficiently regulate the voltage at below resonant mode, while the alternative control approach using a 50% duty cycle may be limited to operating at above resonant mode when regulating the output voltage Vdc. When operating at above resonant mode, the higher switching frequency Fs lowers the peak magnetizing current iLm. However, at above resonant mode, the turn off current i_{off} for switches Q1 and Q2 is much higher than the peak magnetizing current iLm because before the current within the switches Q1 and Q2 equals the magnetizing current iLm, the switches Q1 and Q2 are turned off due to the higher switching frequency Fs. Therefore, the turn-off current i_{off} under the alternative control approach (i.e., 50% duty cycle) in above-resonant mode is worse than i_{off} under the below-resonant mode. This is due to the fact that the switches Q1 and Q2 are turned off when the resonant current is not close to zero.

Under the proposed constant on-time control method, soft switching can be leveraged for the synchronous rectifiers SR in the rectifier stage of circuit 500. As the synchronous rectifiers SR in the rectifier stage of circuit 500 always turn off with a small slew rate resonant current iᵣ, ZCS for the turn-off of the synchronous rectifiers can be used to reduce the associated switching losses.

A further benefit of the proposed constant on-time control method is that the switches Q1 and Q2 of circuit 500 can be turned on using ZCS. It should be noted that even under ZCS, the discharge from the output capacitor of switches Q1 and Q2 may cause some power loss. However, since the voltage across the switches Q1 and Q2 is very small at turn-on, this power loss is minimized. For example, the power loss at turn-on for switches Q1 and Q2 under the proposed constant on-time control can be calculated as:

$$Pon = \frac{1}{2} Coss \cdot {( 2 Vb )}^{2} Fs \qquad ( 16 )$$

Where Pon is the power loss at turn-on and Coss is the output capacitance between the drain and source of switches Q1 and Q2. For example, for a typical 40V MOSFET, Coss will be about 50 nF, considering a 4V input voltage Vb, and 200 kHz switching frequency, the power loss will be about 0.32 W.

A fulsome simulation was completed for both the constant duty cycle (i.e., 50%) control method and the proposed constant ON-time control method under identical conditions, and the results of the simulations were compared. The specifications of circuit 500 used for the simulation of both the constant duty cycle control method and the proposed constant on-time control method are listed in Table 1.

TABLE 1
Converter's specifications for simulations

| | |
|---|---|
| Parameter | Value |

| Vb | 2.6 V, 3.7 V | | Input voltage range |
|---|---|---|---|
| Vo | 330 | V | Output voltage |
| Po | 300 | W | Output power |
| N | 64 | | Transformer's turns ratio |
| Lr | 33 | uH | Resonant inductor |
| Cr = 2Cr1 = 2Cr2 | 34 | nF | Resonant capacitor |
| Lm | 327 | uH | Magnetizing inductor |
| Fr | 150 | kHz | Resonant frequency |

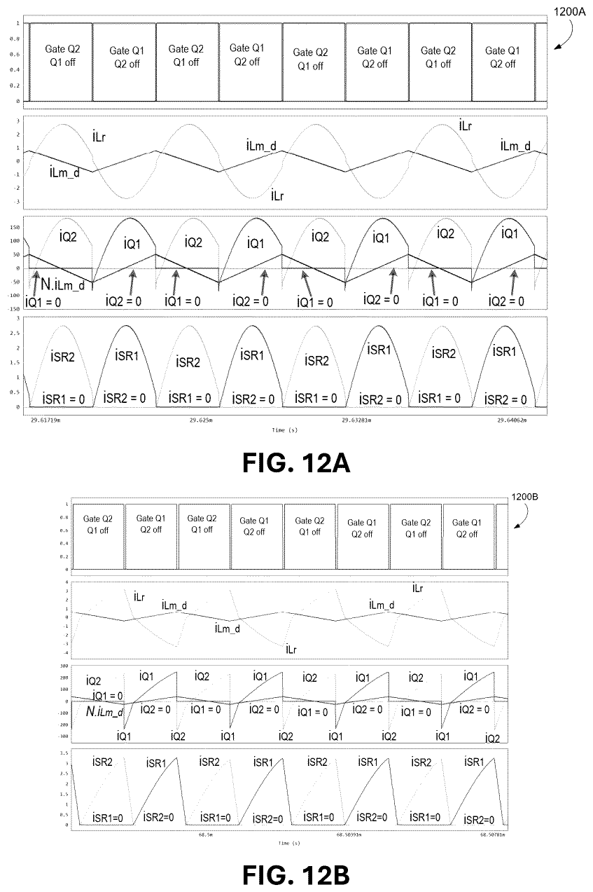

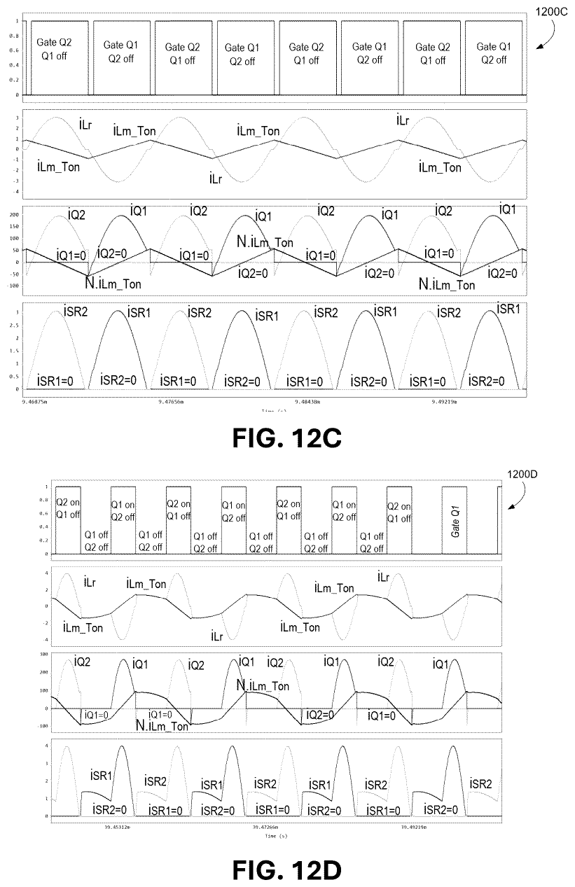

During the simulation, the input voltage Vb was tested at 2.6V and 3.7V, and the output voltage Vdc was regulated at 330V. The simulation results for both control methods are presented in FIG. 12A-12D, where the gate drive signals of switches Q1 and Q2, resonant inductor current iLr and magnetizing inductor current iLm, switch current iQ1, iQ2 and SR current iSR1, iSR2 are shown. The results from the simulations in FIGS. 12A-12D are also summarized in Table 2.

FIG. 12A shows the simulations results 1200A for the constant duty cycle control method in which Vb=2.6V. Under this testing condition, the switching frequency Fs is 158 kHz which is close to the resonant frequency Fr, and the turn-off current i_{off} is around 75 A for switches Q1 and Q2. Results 1200A also show the magnetizing current N.i_{Lm_d} at the primary side (battery side). The peak value of the primary side magnetizing current N.i_{Lm_d} is 50 A, and it can be observed that the turn-off current i_{off} of switches Q1 and Q2 is higher than the peak value of the primary side magnetizing current, which is expected due to switches Q1 and Q2 turning off before the switch current iQ1 and iQ2 reaches the primary side magnetizing current N.i_{Lm_d}. Results 1200A indicate that with alternative control methods utilizing constant duty cycle (50%), the turn off current of switches Q1, Q2 (e.g., MOSFETs) are higher than needed, therefore incurring unnecessary additional turn off loss, which is not desirable.

FIG. 12B shows the simulations results 1200B for the constant duty cycle control method in which Vb=3.7V. Under this testing condition, the switching frequency Fs is increased up to 352 kHz, which is 235% more than the resonant frequency Fr, and the turn-off current for switches Q1 and Q2 is 230 A. As mentioned before, for constant duty cycle control, a converter, such as circuit 500, may have to operate at above resonant mode to reduce the voltage gain and regulate the output voltage. In simulation results 1200B, it can be seen that to achieve the desired voltage gain needed to regulate the input voltage Vb to the desired output voltage Vdc (i.e., 330V), the switching frequency Fs is increased by almost 2.35 times more than the resonant frequency Fr. In this condition, circuit 500 does not resonate anymore, and the waveforms are changing linearly. Therefore, the turn-off current i_{off} for switches Q1 and Q2 is very high as the timing of turn-off occurs at the peak resonant current iLr, which is around 225 A. This high turn-off current i_{off}, in tandem with the high switching frequency leads to a very large switching loss. Simulation results 1200B also show the magnetizing current at the primary side (N.i_{Lm_d}). The peak magnetizing current value N.i_{Lm_d} at the primary side is 32 A, and it can be observed that the turn-off current i_{off} is much higher than the peak magnetizing current value N.i_{Lm_d} as discussed for FIG. 12A.

FIG. 12C shows the simulations results 1200C for the proposed constant on-time control method in which Vb=2.6V. Under this testing condition, the switching frequency Fs is 141 kHz which is close to the resonant frequency Fr, and the turn-off current i_{off} for switches Q1 and Q2 is 55 A. Comparing the turn-off current i_{off} for switches Q1 and Q2 between the constant duty cycle control (1200A) and the proposed constant on-time control (1200C) under the same conditions, the turn-off current i_{off} for switches Q1 and Q2 in 1200A is 75 A, which is 36% higher than the turn-off current i_{off} for switches Q1 and Q2 in 1200C. Simulation results 1200C also shows the primary side magnetizing current N.i_{Lm_Ton}. The peak primary side magnetizing current value N.i_{Lm_Ton} is 55 A, which is equal to the turn-off current of the switches Q1 and Q2. As compared to the results 1200A shown for the alternative control strategy (FIG. 12A), the turn off current for results 1200C is reduced from 75 A to 55 A, which in turn reduces turn off loss.

FIG. 12D shows the simulations results 1200D for the proposed constant on-time control method in which Vb=3.7V. Under this testing condition, the switching frequency Fs is 69 kHz which is close to the resonant frequency, and the turn-off current for switches Q1 and Q2 is 95 A. Comparing the turn-off current i_{off} for switches Q1 and Q2 between the constant duty cycle control (1200B) and the proposed constant on-time control (1200D) under the same conditions, the turn-off current i_{off} for switches Q1 and Q2 in 1200B is 230 A, which is 232% higher than the turn-off current i_{off} for switches Q1 and Q2 in 1200D. Further, the switching frequency Fs in 1200B is 352 kHz, which is 526% higher than the switching frequency Fs in 1200D. Simulation results 1200D also shows the primary side magnetizing current N.i_{Lm_Ton}. The peak primary side magnetizing current value N.i_{Lm_Ton} is 95 A, which is equal to the turn-off current of the switches Q1 and Q2. As compared to the results under alternative control strategy (FIG. 12B), the turn off current here is reduced from around 225 A to 95 A, which in turn reduces turn off loss.

Considering the simulation results in 1200C and 1200D for the constant on-time control method, it is expected, according to equation (12), that since the input voltage Vb is increased from 2.6V to 3.7V, the peak primary side magnetizing current value N.i_{Lm_Ton} (or the turn-off current for switches Q1 and Q2) should increase from 55 A to 55 A*3.7V/2.6V=78 A.

However, the peak primary side magnetizing current value N.i_{Lm_Ton} in 1200D is 95 A. This discrepancy is due to the assumption in equation (12) that the primary side magnetizing current value N.i_{Lm_Ton} will be constant when both switches Q1 and Q2 are in the off-state. However, as can be seen in FIG. 12D, when the switches Q1 and Q2 are in the off state, the primary side magnetizing current value N.i_{Lm_Ton} slightly decreases due to switches Q1 and Q2's body diode voltage drop, which results in the discrepancy between the actual outcome in simulation result 1200D and the theoretical outcome in equation (12). Regardless, the simulation results 1200C and 1200D using the proposed constant ON-time control for circuit 500 verify the improvements in circuit efficiency and power loss reduction expected over alternative voltage regulation control approaches, such as constant duty cycle control.

In some embodiments, under constant on-time control, the current ripple of the magnetic components in circuit 500 may be kept constant while operating at a lower switching frequency. This may lower magnetic core and AC losses.

The simulation results 1200C and 1200D in FIGS. 12C and 12D also show that under constant on-time control, the synchronous rectifiers SR1, SR2 and primary switches Q1, Q2 may turn-off under ZCS conditions (i.e., iSR1, iSR2 iQ1, iQ2 all equal OA at turn-off).

TABLE 2
Simulations results comparison

| | | 50% duty | Constant |
|---|---|---|---|
| | | cycle | ON-time |
| | Parameter | control | control |
| Vb = 2.6 V | Turn-off current (A) | 75 | 55 |
| | Fs (kHz) | 158 | 141 |
| Vb = 3.7 V | Turn-off current (A) | 230 | 95 |
| | Fs (kHz) | 352 | 69 |

In some embodiments, the proposed constant on-time control method can be implemented with variations of the high step-up DC-DC converter shown in circuit 500. For example, the primary side of circuit 500 can be configured with a full-bridge or half-bridge switching network.

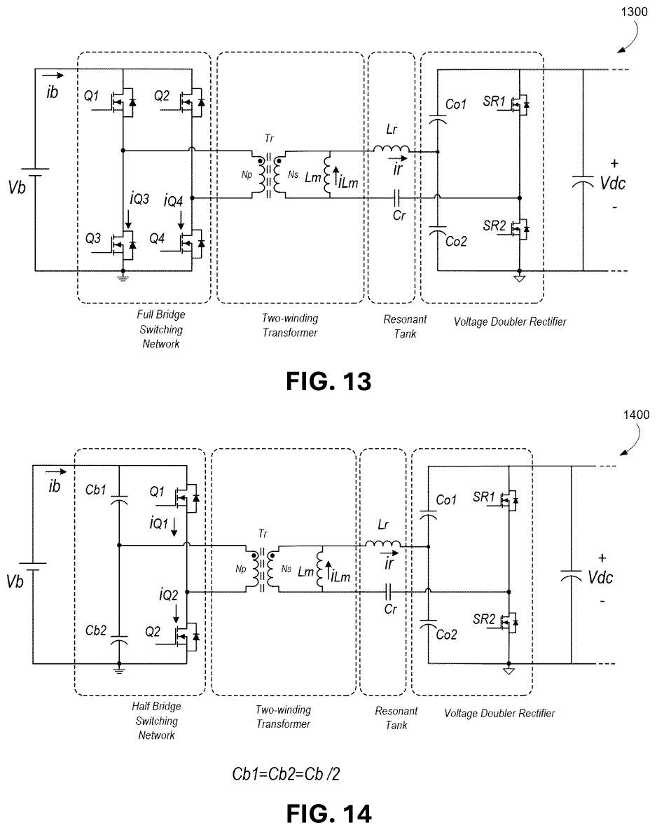

In FIG. 13, a converter circuit 1300 is shown which has a full bridge switching topology on the primary side. In circuit 1300, the primary side has four switches (Q1, Q2, Q3, and Q4) and a two-winding transformer Tr (one primary and one secondary winding). The secondary side contains a resonant tank and a voltage doubler rectifier. It is noted that other secondary configurations, such as a full-bridge rectifier (with four MOSFETs) and a split resonance capacitor rectifier (two MOSFETs and two resonant capacitors) can also be used.

When operating circuit 1300 under the proposed constant on-time control method for voltage regulation, the voltage and current waveforms applied to the secondary winding, the resonant tank and the rectifier circuit in circuit 1300 are substantively identical to that described above for a push-pull converter such as circuit 500. Further, as will be discussed below, the principle of operation, waveforms and the performance of circuit 1300 under constant on-time control is identical to that discussed above for a push-pull converter topology such as circuit 500.

In FIG. 14, a converter circuit 1400 is shown which has a half-bridge switching topology on the primary side. Circuit 1400 has a two-winding transformer Tr (one primary and one secondary winding), and a switching network on the primary side having two primary switches (Q1 and Q2) and two capacitors (Cb1 and Cb2).

When operating circuit 1400 under the proposed constant on-time control method for voltage regulation, the voltage applied to the secondary winding, the resonant tank and the rectifier of circuit 1400 are halved in comparison to the push-pull converter topology shown in circuit 500, due to the battery voltage Vb being split between Cb1 and Cb2. However, aside from the reduction in voltage gain due to the half-bridge switching network in circuit 1400, the waveforms, principle of operation and performance of circuit 1400 under constant on-time control is substantively similar to that discussed above for a push-pull converter topology such as circuit 500.

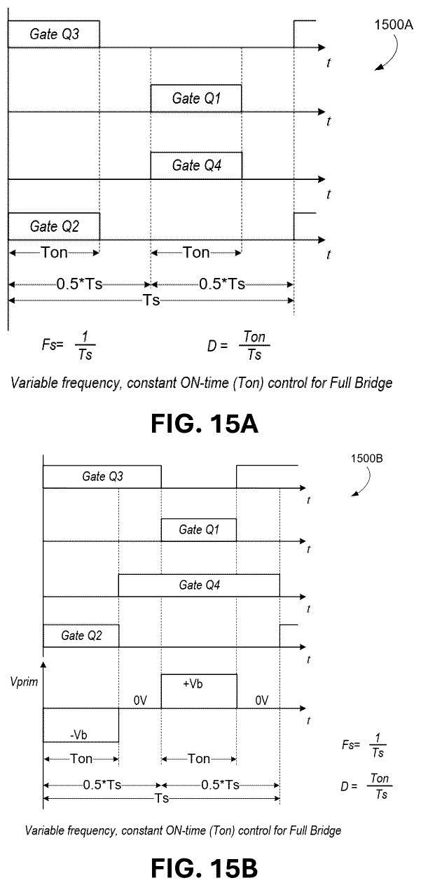

FIG. 15A shows a gate pulse pattern 1500A (gate drive strategy) of switches Q1-Q4 in the full-bridge topology of circuit 1300 under constant on-time control. According to the gate pulse pattern 1500A for circuit 1300, switches Q2 and Q3 are initially in the on-state for a set duration (Ton). After the duration of Ton, switches Q2 and Q3 are transitioned to the off-state, and all of switches Q1-Q4 are now in the off-state. At t=Ts/2 (i.e., half the switching period), Q1 and Q4 are transitioned to the on-state for a set duration (Ton). After the duration of Ton, switches Q1 and Q4 are transitioned to the off-state. All of switches Q1-Q4 are now in the off-state and will remain off for the remainder of the initial switching period Ts. The gate pulse pattern 1500A for circuit 1300 will achieve the same waveform and performance under constant on-time control as the push-pull topology discussed above in circuit 500, since both control regimes generate the same voltage waveform at the secondary side of the transformer Tr.

FIG. 15B shows a gate pulse pattern 1500B (gate drive strategy) of switches Q1-Q4 in the full-bridge topology of circuit 1300 under constant on-time control. In gate pulse pattern 1500B, switches Q2 and Q3 are initially in the on-state for a set duration (Ton). At t=Ton, switch Q2 transitions to the off-state but switch Q3 remains in the on-state. Further, when switch Q2 transitions to the off-state at t=Ton, switch Q4 transitions to the on-state. Therefore, for the time interval Ton<t<0.5 Ts, both switches Q3 and Q4 are in the on-state. The same condition is true for the second half of the switching cycle Ts. When switch Q1 transitions to the off-state, switch Q4 remains in the on-state, and switch Q3 transitions to the on-state. Therefore, in the second half of switching period Ts, both switches Q3 and Q4 are in the on-state for the time interval 0.5*Ts+Ton<t<Ts.

In the gate pulse pattern 1500A shown in FIG. 15A, primary winding of transformer Tr is an open circuit when all switches Q1-Q4 are in the off-state (i.e., time interval t between Ton and 0.5*Ts). In the gate pulse pattern 1500B shown in FIG. 15B, the primary winding of transformer Tr is short circuited when both switches Q3 and Q4 are in the on-state. For gate pulse pattern 1500B, by short circuiting the primary winding of transformer Tr when switches Q3 and Q4 are both in the on-state, the risk of transformer saturation due to volt-second unbalance (average flux across transformer Tr does not return to zero) can be minimized or negated. This can be seen in the gate pulse pattern 1500B in FIG. 15B, where the voltage waveform (Vₚᵣᵢₘ) across the primary winding of transformer Tr is shown, and during intervals where both switches Q3 and Q4 are in the on-state, Vₚᵣᵢₘ is equal to zero (i.e., volt-second balance is achieved). In most cases, FIG. 15B is a preferred implementation strategy. For example, in home energy storage applications, the battery voltage is around 48V, and the AC voltage is 120V or 220V. A Full-Bridge LLC converter as shown in FIG. 13 can be controlled using the gate pulse pattern 1500B to maintain volt-second balance. The overlap strategy in 1500B may minimize flux imbalance in the core of transformer Tr, reducing the risk of overheating and improving efficiency, making it ideal for continuous, high-duty use cases in home power systems.

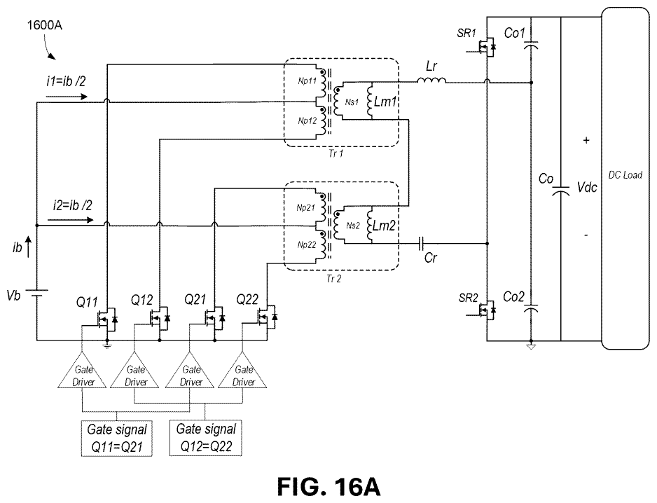

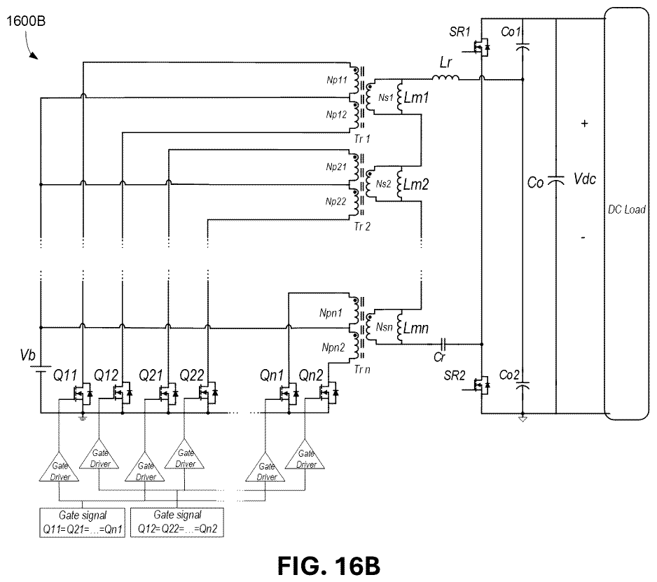

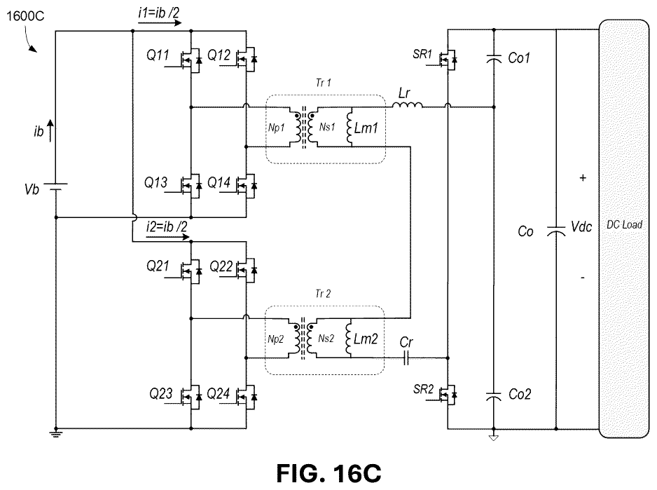

In a further embodiment for constant on-time control of a converter used for voltage regulation, a push-pull LLC converter, such as circuit 1600A in FIG. 16A, may have two transformers which are connected in parallel, on the primary side, to two switching networks, and the secondary side of the two transformers can be connected in series to a resonant tank and rectifier. By connecting two transformers in parallel on the primary side, circuit 1600A may produce two times the output power compared to a single push-pull LLC converter, such as that shown in circuit 500. For example, circuit 1600A in FIG. 16A has two transformers Tr and Tr2 connected in parallel on the primary side and connected in series on the secondary side. On the primary side of circuit 1600A, transformer Tr is connected to a first switching network containing switches Q11 and Q12, and transformer Tr2 is connected to a second switching network containing switches Q21 and Q22. The first and second switching networks are connected in parallel to battery Vb.

As the two-phase primary side of circuit 1600A is essentially a mirroring of the primary side of circuit 500, the constant on-time control approach shown in FIGS. 7A-7C can be used for the gate drive signals of switches Q11, Q12, Q21 and Q22. For example, with reference to FIGS. 7A-7C, the gate drive signals for switches Q11 and Q21 of circuit 1600A can be identical to the gate drive signal for switch Q1 in circuit 500, and the gate drive signals for switches Q12 and Q22 of circuit 1600A can be identical to the gate drive signal for switch Q2 in circuit 500.

On the secondary side of circuit 1600A, transformers Tr and Tr2 are connected in series with a resonant tank containing resonant inductor Lr and resonant capacitor Cr. The resonant tank of circuit 1600A is connected to a rectifier having a half bridge voltage doubler topology, however, other rectifier topologies (such as full wave rectifier, split resonant capacitor voltage doubler, etc.) can also be used.

As the secondary side of circuit 1600A contains identical components to the secondary side of circuit 500 (i.e., single push-pull LLC converter), the topology in circuit 1600A increases the number of transformers (i.e., Tr2), leading to a corresponding increase in output power, without increasing, compared to circuit 500, the component cost and complexity of the secondary side of the converter.

In some embodiments, the two-phase push-pull converter topology of circuit 1600A may double the output power compared to the single push-pull converter topology seen in circuit 500. Therefore, circuit 1600A may be preferred for high output power charging. Further, a technical benefit of circuit 1600A is that, compared to other approaches for high output power converters, only the transformer and switching network (i.e., Tr2 and Q21, Q22) are required as additional components, instead of a complete converter circuit including a second resonant tank and second rectifier stage. Further, by maintaining a single resonant tank (i.e., Lr and Cr) connected in series with transformers Tr and Tr2, mismatches caused by component value tolerances among multiple resonant tanks is mitigated in circuit 1600A.

A further technical benefit of circuit 1600A is that the transformers Tr and Tr2 have the same winding voltage and winding current such that transformers Tr and Tr2 have equal load distribution and minimal circulating currents. Therefore, power sharing issues between Tr and Tr2, and the overheating and overloading that can arise from uneven load distribution, are mitigated within circuit 1600A. For example, as the secondary windings of transformers Tr and Tr2 are connected in series, the secondary current of the transformers Tr and Tr2 will be equal, leading to the same primary current (i1=i2). In addition, since the primary windings of transformers Tr and Tr2 are connected in parallel, the voltage across the primary windings is always equal.

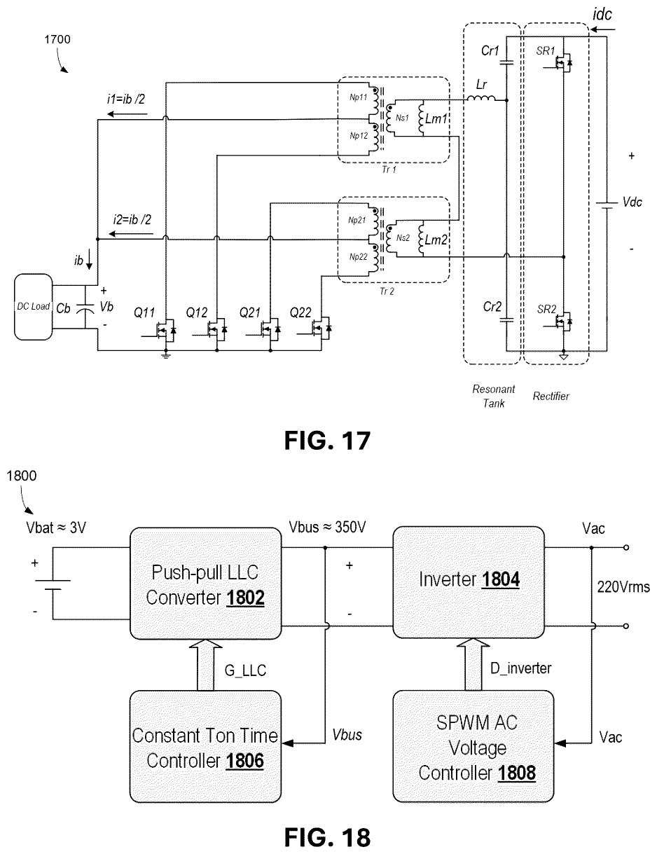

FIG. 17 shows a circuit 1700 having a two-phase transformer topology, in which transformers Tr and Tr2 are connected in parallel on the primary side and in series on the secondary side. Circuit 1700 is a variant of circuit 1600A, and can be used for bidirectional operation in which power can be transferred from the high voltage side to the low voltage side, and vice-versa. The operational principles for constant on-time control discussed above for circuit 1600A may therefore apply to circuit 1700. In circuit 1700, the primary side is identical to that of circuit 1600A, but the secondary side of circuit 1700 has a resonant tank with a split resonant capacitor (Cr1 and Cr2) and a voltage doubler rectifier stage. For example, when transferring power from the high voltage side (Vdc) to the low voltage side (Vb) of circuit 1700, the switches SR1 and SR2 at the high voltage side operate as the main switches, and the switches Q11, Q12, Q21, Q22 at the low voltage side operate as synchronous rectifiers. In this case, SR1 and SR2 may operate at 50% duty cycle. The secondary windings (Ns1, Ns2) of transformers Tr and Tr2 are connected in series, and the primary windings (Np11, Np12 and Np21, Np22) are connected in parallel.

In FIG. 16B, a variant of circuit 1600A is shown in which three or more transformers T1, Tr2, Trn of a push-pull LLC converter can be connected in parallel on the primary side and in series on the secondary side. In circuit 1600B shown in FIG. 16B, the same methodology and operational characteristics discussed above for FIG. 16A can be applied to three or more push-pull LLC converters operating under constant on-time control to achieve higher output power.

Circuit 1600B may have three or more transformers each connected in parallel, on the primary side, to three or more corresponding switching networks, and the secondary side can be connected in series to a single resonant tank and rectifier. By connecting three or more transformers in parallel on the primary side, circuit 1600B may produce three or more times the output power compared to a single push-pull LLC converter, such as that shown in circuit 500. For example, circuit 1600B in FIG. 16B has three transformers T1, Tr2 and Trn connected in parallel on the primary side and connected in series on the secondary side. On the primary side of circuit 1600B, transformer Tr is connected to a first switching network containing switches Q11 and Q12; transformer Tr2 is connected to a second switching network containing switches Q21 and Q22; and transformer Trn is connected to an nth switching network containing Qn1 and Qn2. The three switching networks are connected in parallel to battery Vb.

As mentioned above when discussing circuit 1600A, the constant on-time control approach shown in FIGS. 7A-7C can be used for the gate drive signals of switches Q11, Q12, Q21, Q22, Qn1 and Qn2. For example, with reference to FIGS. 7A-7C, the gate drive signals for switches Q11, Q21, Qn1 of circuit 1600B can be identical to the gate drive signal for switch Q1 in circuit 500; the gate drive signals for switches Q12, Q22, Qn2 of circuit 1600B can be identical to the gate drive signal for switch Q2 in circuit 500.

On the secondary side of circuit 1600B, transformers T1, Tr2 and Trn are connected in series with a resonant tank containing resonant inductor Lr and resonant capacitor Cr. The resonant tank of circuit 1600B is connected to a rectifier having a half bridge voltage doubler topology, however, other rectifier topologies (such as full wave rectifier, split resonant capacitor voltage doubler, etc.) can also be used.

In another embodiment for constant on-time control of a converter used for voltage regulation, a full-bridge converter, such as circuit 1600C in FIG. 16C, may have two transformers connected in parallel on the primary side to two switching networks, and the secondary side can be connected in series to a resonant tank and rectifier. Circuit 1600C may produce two times the output power compared to a single full-bridge converter, such as that shown in circuit 1300. For example, circuit 1600C has two transformers Tr and Tr2 connected in parallel on the primary side and connected in series on the secondary side. On the primary side of circuit 1600C, transformer Tr is connected to a first full-bridge switching network containing switches Q11, Q12, Q13, Q14, and transformer Tr2 is connected to a second full-bridge switching network containing switches Q21, Q22, Q23, Q24. The first and second full-bridge switching networks are connected in parallel to battery Vb.

As the two-phase primary side of circuit 1600C is essentially a mirror of the primary side of circuit 1300, the constant on-time control approach shown in FIGS. 15A and 15B can be used for the gate drive signals of switches Q11, Q12, Q13, Q14, Q21, Q22, Q23 and Q24. For example, with reference to FIGS. 15A and 15B, the gate drive signals for switches Q11 and Q21 of circuit 1600C can be identical to the gate drive signal for switch Q1 in circuit 1300; the gate drive signals for switches Q12 and Q22 of circuit 1600C can be identical to the gate drive signal for switch Q2 in circuit 1300; the gate drive signals for switches Q13 and Q23 of circuit 1600C can be identical to the gate drive signal for switch Q3 in circuit 1300; and the gate drive signals for switches Q14 and Q24 of circuit 1600C can be identical to the gate drive signal for switch Q4 in circuit 1300.

On the secondary side of circuit 1600C, transformers Tr and Tr2 are connected in series with a resonant tank containing resonant inductor Lr and resonant capacitor Cr. The resonant tank of circuit 1600C is connected to a rectifier having a half bridge voltage doubler topology, however, other rectifier topologies (such as full wave rectifier, split resonant capacitor voltage doubler, etc.) can also be used.

Similar to the discussion surrounding circuit 1600A, transformers Tr and Tr2 in circuit 1600C have the same winding voltage and winding current such that transformers Tr and Tr2 have equal load distribution and minimal circulating currents.

FIG. 18 shows a control diagram 1800 for controlling a Push-Pull LLC converter, such as any one of circuits 400A, 400B, 500, 500-1, 1600A-1600B and 1700. In operation, control diagram 1800 may be used within a portable power station (PPS) where the energy source is a battery with DC voltage (Vbat) around 3V and an AC output voltage (Vac) of 220V (rms). The push-pull LLC converter 1802 with constant on-time control converts the battery voltage Vbat (around 3V) to a DC bus voltage (Vbus) of around 350V. This is a voltage gain of around 120 times. An inverter 1804 is coupled to the push-pull LLC converter 1802 to convert the DC bus voltage from 350 Vdc to an AC output voltage of 220 Vac. The constant on-time time controller 1806 is configured to generate the gate drive signals (such as those seen in FIGS. 7A-7C) for the primary side switches for push-pull LLC converter 1802. The constant on-time controller 1806 may also be configured to modulate the switching frequency (Fs) of the primary switches to regulate the Vbus to around 350V. The SPWM AC voltage controller 1808 is configured to regulate the AC output voltage to around 220 Vrms. Control diagram 1800 may be applicable to additional converter types, including converters with full-bridge and half-bridge switching networks.

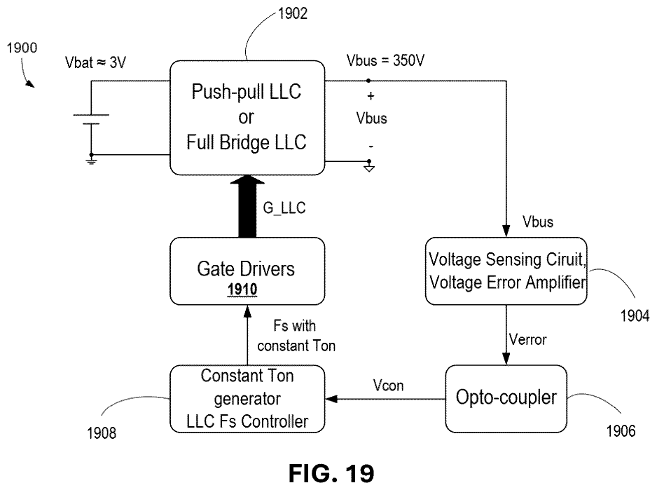

FIG. 19 shows a control block diagram 1900 of the proposed constant on-time control. A push-pull LLC converter, such as circuit 500, or a full-bridge LLC converter, such as circuit 1300, is used as converter 1902 to convert a battery voltage Vbat (around 3V) to a DC bus voltage Vbus (around 350V). A voltage sensing and error amplifier circuit 1904 is configured to sense the DC bus voltage Vbus and generate an error signal, Verror. Verror may be a voltage signal representing the delta between the desired Vbus (i.e., 350V) and the actual Vbus generated by converter 1902. An opto-coupler 1906 may be coupled to the voltage sensing and error amplifier circuit 1904 and be configured to transfer the error signal Verror from the output side of converter 1902 (i.e., secondary side) to the battery side of converter 1902 (i.e., primary side). Opto-coupler 1906 receives as an input the Verror and may be configured to output a corresponding Vcon signal to a controller 1908. Vcon is received by controller 1908, which is configured to produce a switching frequency Fs based on Vcon for constant on-time control of the primary switches of converter 1902. A gate driver 1910 is coupled between the controller 1908 and the primary switches of converter 1902. Gate driver 1910 may be configured to receive the switching frequency Fs from controller 1908 and generate constant on-time gate drive signals for the primary switches of converter 1902 to regulate the input voltage Vbat to the desired bus voltage Vbus (i.e., 350V).

In some embodiments, voltage sensing and error amplifier circuit 1904, opto-coupler 1906, Controller 1908 and gate drivers 1910 may be housed within constant on-time controller 1806 shown in FIG. 18.

The term “connected” or “coupled to” may include both direct coupling (in which two elements that are coupled to each other contact each other) and indirect coupling (in which at least one additional element is located between the two elements).

Although the embodiments have been described in detail, it should be understood that various changes, substitutions and alterations can be made herein without departing from the scope. Moreover, the scope of the present application is not intended to be limited to the particular embodiments of the process, machine, manufacture, composition of matter, means, methods and steps described in the specification.

As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized. Accordingly, the appended claims are intended to include within their scope such processes, machines, manufacture, compositions of matter, means, methods, or steps.

As can be understood, the examples described above and illustrated are intended to be exemplary only.

What is claimed is:

1. A method for constant on-time control of a push-pull LLC converter, the converter having a transformer with a primary side coupled in series with a switching network having two switches Q1 and Q2, and a secondary side coupled to a resonant tank and a rectifier, where the primary side receives an input DC voltage supply and the rectifier outputs a DC bus voltage, the method comprising:
setting a switching frequency for the switches Q1 and Q2 to regulate the DC bus voltage, the switching frequency having a corresponding switching period representing a full cycle of both switches Q1 and Q2; and
modulating the switches Q1 and Q2 180 degrees out of phase between an on-state and an off-state, and switches Q1 and Q2 are kept in the on-state for a fixed time duration that is at most half the switching period.

2. The method of claim 1, further comprising generating, from a gate driver, a gate voltage for each of the primary switches Q1 and Q2 to transition each of the primary switches between the on-state and the off-state during the switching period, the primary switches entering the on-state upon receiving a high gate voltage and entering the off-state upon receiving a low gate voltage.

3. The method of claim 2, further comprising:
transmitting, at the start of the switching period, the high gate voltage to the primary switch Q1 for a first fixed time duration to transition the primary switch Q1 to the on-state.
transmitting, upon expiry of the first fixed time duration, the low gate voltage to the primary switch Q1 to transition the primary switch Q1 to the off-state;
transmitting, at a half point of the switching period, the high gate voltage to the primary switch Q2 for a second fixed time duration to transition the primary switch Q2 to the on-state;
transmitting, upon expiry of the second fixed time duration, the low gate voltage to the primary switch Q2 to transition the primary switch Q2 to the off-state;
sensing the DC bus voltage, through a voltage sensor, and setting a modified switching frequency of the primary switches based on a delta between the sensed DC bus voltage and a desired DC bus voltage.

4. The method of claim 3, wherein the modified switching frequency is lower than a resonant frequency of the resonant tank.

5. The method of claim 3, wherein the rectifier is one of a voltage multiplier, full-bridge or half-bridge topography.

6. The method of claim 3, wherein:
the converter has two transformers coupled in parallel to the input DC voltage, where the primary side of the first transformer is connected to the switching network containing the primary switches Q1 and Q2, and the second transformer is connected to a second switching network containing primary switches Q3 and Q4; and
the gate voltage generated by the gate driver for the primary switch Q3 is the same as the gate voltage for the primary switch Q1, and the game voltage generated by the gate driver for the primary switch Q4 Is the same as the gate driver voltage generated for the primary switch Q2.

7. The method of claim 6, wherein the secondary side of the first and second transformers are coupled in series to the resonant tank and the rectifier.

8. The method of claim 3, wherein transitioning the primary switches Q1 and Q2 from the on-state to the off-state occurs after a peak primary side magnetizing current is equal to a switch current, wherein the peak primary side magnetizing current is a measure of current flow across a magnetizing inductor of the transformer multiplied by the turn ratio of the transformer, and the switch current is a measure of current flow across the primary switches Q1 and Q2 when they are in the on-state.

9. The method of claim 3, wherein both primary switches Q1 and Q2 are in the off-state between the expiry of the fixed time duration and the half point of the switching period, and wherein the resonant tank has an inherent resonant period, and the fixed time duration is about equal to the resonant period.

10. A method for constant on-time control of a full-bridge LLC converter, the converter containing a transformer with a primary side coupled in series to a switching network with four switches Q1-Q4, and a secondary side coupled to a resonant tank and a rectifier, where the primary side receives an input DC voltage supply and the rectifier outputs a DC bus voltage, the method comprising:
setting a switching frequency for the switches Q1 and Q2 to regulate the DC bus voltage, the switching frequency having a corresponding switching period representing a full cycle of both switches Q1 and Q2;
modulating the switches Q1 and Q2 180 degrees out of phase between an on-state and an off-state, and switches Q1 and Q2 are kept in the on-state for a fixed time duration that is at most half the switching period;
modulating the switches Q3 and Q4 between the on-state and the off-state, wherein the switch Q3 is in the on-state longer than, and overlapping with, the fixed time duration of switch Q2, and the switch Q4 is in the on-state longer than, and overlapping with, the fixed time duration of switch Q1.

11. The method of claim 10, further comprising generating, from a gate driver, a gate voltage for each of the primary switches Q1-Q4 to transition each of the primary switches between the on-state and the off-state during the switching period, the primary switches entering the on-state upon receiving a high gate voltage and entering the off-state upon receiving a low gate voltage.

12. The method of claim 11, further comprising:
transmitting, at the start of the switching period, the high gate voltage to the primary switches Q2 and Q3 for a first fixed time duration to transition the primary switches Q2 and Q3 to the on-state.
transmitting, upon expiry of the first fixed time duration, the low gate voltage to the primary switch Q2 to transition the primary switch Q2 to the off-state, and maintaining the high gate voltage to the primary switch Q3 until the expiry of half the switching period;
transmitting, upon expiry of the first fixed time duration, the high gate voltage to the primary switch Q4 to transition the primary switch Q4 to the on-state;
transmitting, at a half point of the switching period, the high gate voltage to the primary switch Q1 for a second fixed time duration to transition the primary switch Q1 to the on-state;
transmitting, upon expiry of the second fixed time duration, the low gate voltage to the primary switch Q1 to transition the primary switch Q1 to the off-state, and maintaining the high gate voltage to the primary switch Q4 until expiry of the full switching period;
transmitting, upon expiry of the second fixed time duration, the high gate voltage to the primary switch Q3 to transition the primary switch Q3 to the on-state; and
sensing the DC bus voltage, through a voltage sensor, and modifying the switching frequency of the primary switches based on a delta between the sensed DC bus voltage and a desired DC bus voltage.

13. The method of claim 12, wherein the modified switching frequency is lower than a resonant frequency of the resonant tank.

14. The method of claim 12, wherein the rectifier is one of a voltage multiplier, full-bridge or half-bridge topography.

15. The method of claim 12, wherein the transformer is short-circuited when both primary switches Q3 and Q4 are in the on-state.

16. The method of claim 12, wherein:
the converter has two transformers coupled in parallel to the input DC voltage, where the primary side of the first transformer is connected to the switching network containing the primary switches Q1-Q4, and the primary side of a second transformer is connected to a second switching network containing primary switches Q5-Q8; and
the gate voltage generated by the gate driver for the primary switch Q5 is the same as the gate voltage for the primary switch Q1, the gate voltage generated by the gate driver for the primary switch Q6 is the same as the gate driver voltage generated for the primary switch Q2, the game voltage generated by the gate driver for the primary switch Q7 is the same as the gate driver voltage generated for the primary switch Q3, and the game voltage generated by the gate driver for the primary switch Q8 Is the same as the gate driver voltage generated for the primary switch Q4.

17. The method of claim 16, wherein the secondary side of the first and second transformers are coupled in series to the resonant tank and the rectifier.

18. The method of claim 12, wherein transitioning the primary switches Q1 and Q2 from the on-state to the off-state occurs after a peak primary side magnetizing current is equal to a switch current, wherein the peak primary side magnetizing current is a measure of current flow across a magnetizing inductor of the transformer multiplied by the turn ratio of the transformer, and the switch current is a measure of current flow across the primary switches Q1 and Q2 when they are in the on-state.

19. The method of claim 12, wherein both primary switches Q1 and Q2 are in the off-state between the expiry of the fixed time duration and the half point of the switching period.

20. A non-transitory computer readable medium, storing machine readable instructions, which when executed by a processor, cause the processor to perform a method for constant on-time control of a push-pull LLC converter, the converter having a transformer with a primary side coupled in series with a switching network having two switches Q1 and Q2, and a secondary side coupled to a resonant tank and a rectifier, where the primary side receives an input DC voltage supply and the rectifier outputs a DC bus voltage, the method comprising:
setting a switching frequency for the switches Q1 and Q2 to regulate the DC bus voltage, the switching frequency having a corresponding switching period representing a full cycle of both switches Q1 and Q2; and
modulating the switches Q1 and Q2 180 degrees out of phase between an on-state and an off-state, and switches Q1 and Q2 are kept in the on-state for a fixed time duration that is at most half the switching period.
